(19) United States
(12) Patent Application Publication
(10) Pub. No.: US 2024/0222236 A1
(43) Pub. Date: Jul. 4, 2024

(54) ELECTRONIC DEVICE AND MANUFACTURING METHOD THEREOF

(71) Applicant: FUJI ELECTRIC CO., LTD., Kawasaki-shi (JP)

(72) Inventor: Shinji TADA, Matsumoto-city (JP)

(73) Assignee: FUJI ELECTRIC CO., LTD., Kawasaki-shi (JP)

(21) Appl. No.: 18/518,096

(22) Filed: Nov. 22, 2023

(30) Foreign Application Priority Data
Dec. 28, 2022 (JP) 2022-212278

(51) Int. Cl. H01L 23/495; H01L 23/00; H01L 25/065

(52) U.S. Cl. CPC H01L 23/49575; H01L 23/4951; H01L 23/49527; H01L 24/05; H01L 24/29; H01L 25/0652; H01L 2224/05005; H01L 2224/05022; H01L 2224/29005; H01L 2224/29022; H01L 2924/13091; H01L 2924/15787; H01L 2924/181

(57) ABSTRACT

An electronic device includes a first terminal having a first center portion, and a first external and internal end portions that are respectively bent at opposing ends of the first center portion to extend in first and second directions opposite to each other, a second terminal having a second center portion, and a second external and internal end portions that are respectively bent at opposing ends of the second center portion to extend in the first and second directions, an insulating sheet sandwiched by the first and second center portions, and a casing having a first resin in contact with the first and second center portions, and a second resin portion that holes the first resin portion. The first resin portion holds at least a part of the first and second terminals and the insulating sheet, with the first and second external end portions being exposed to an outside thereof.

### CROSS-REFERENCE TO RELATED APPLICATION

This application is based upon and claims the benefit of priority of the prior Japanese Patent Application No. 2022-212278, filed on Dec. 28, 2022, the entire contents of which are incorporated herein by reference.

### BACKGROUND OF THE INVENTION

### 1. Field of the Invention

The embodiments discussed herein relate to an electronic device and a manufacturing method thereof.

### 2. Background of the Related Art

In a semiconductor device, positive and negative wirings that are sealed by sealing resin protrude from the sealing resin. In addition, ports at which these positive and negative wirings protrude from the sealing resin are sealed by another piece of sealing resin, and these positive and negative wirings protrude from this another sealing resin (for example, see Japanese Laid-open Patent Publication No. 2019-071784 and Japanese Laid-open Patent Publication No. 2013-009501). Another semiconductor device includes lead frames and a casing, which includes the lead frames. A terminal at one end portion of the individual lead frame protrudes to the outside. This casing is constituted by a combination of a plurality of parts (for example, see Japanese Laid-open Patent Publication No. 2021-150423). In still another semiconductor device, the upper surface of a main terminal having a block shape is exposed to the outside on a casing, and an external connection surface appears on the upper surface (For example, see Japanese Laid-open Patent Publication No. 2020-009834).

End portions of positive and negative main current terminals of a semiconductor device extend from a casing in opposite directions (for example, see Japanese Laid-open Patent Publication No. 2016-066974, Japanese Laid-open Patent Publication No. 2009-081993, and Japanese Laid-open Patent Publication No. 2008-029117). In addition, positive and negative terminals of a semiconductor device sandwich an insulating paper and are exposed to the outside on an end portion of a casing (for example, see Japanese Laid-open Patent Publication No. 2006-086438, International Publication Pamphlet No. 2022/091288, Japanese Laid-open Patent Publication No. 2021-106235, Japanese Laid-open Patent Publication No. 2022-006876, International Publication Pamphlet No. 2019/098368, Japanese Laid-open Patent Publication No. 2010-157565, and International Publication Pamphlet No. 2020/035931). In still another semiconductor device, a positive terminal and a negative terminal sandwiching an insulating layer are formed on a casing (for example, see Japanese Laid-open Patent Publication No. 2016-006834).

### SUMMARY OF THE INVENTION

In one aspect of the embodiments, there is provided an electronic device including: a first terminal having a first center portion, and a first external end portion and a first internal end portion that are respectively connected to opposing ends of the first center portion and respectively extend in a same direction or different directions that are opposite to each other; a second terminal having a second center portion, and a second external end portion and a second internal end portion that are respectively connected to opposing ends of the second center portion and respectively extend in a same direction or different directions that are opposite to each other; an insulating sheet sandwiched by the first and second center portions; and a casing having a first resin portion in contact with the first and second center portions, and a second resin portion that holds the first resin portion, the first resin portion holding at least a part of the first and second terminals and the insulating sheet, with the first and second internal end portions and the first and second external end portions being exposed to an outside thereof.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a plan view of a semiconductor unit included in the semiconductor device according to the first embodiment;

FIG. 3 is a perspective view of a casing included in the semiconductor device according to the first embodiment;

FIG. 4 is a flowchart illustrating a manufacturing method of the semiconductor device according to the first embodiment;

FIG. 5 is a flowchart illustrating a preparation step for the casing of the semiconductor device according to the first embodiment;

FIGS. 6A and 6B illustrate assembling of a terminal body, the assembling being included in the preparation step for the casing according to the first embodiment;

FIGS. 7A and 7B each illustrate molding of a terminal-embedded body with casing material, the molding being included in the preparation step for the casing according to the first embodiment;

FIG. 8 illustrates molding of a nut-embedded body with casing material, the molding being included in the preparation step for the casing according to the first embodiment;

FIGS. 9A to 9C illustrate combining of molded bodies, the combining being included in the preparation step for the casing according to the first embodiment;

FIG. 10 illustrates a second molding step included in the preparation step for the casing according to the first embodiment;

FIGS. 11A and 11B illustrate molding of a nut-embedded body with casing material, the molding being included in a preparation step for a casing according to a second embodiment;

FIGS. 12A and 12B illustrate combining of molded bodies, the combining being included in the preparation step for the casing according to the second embodiment (part 1);

FIGS. 13A and 13B illustrate combining of the molded bodies, the combining being included in the preparation step for the casing according to the second embodiment (part 2);

FIG. 14 illustrates combining of the molded bodies, the combining being included in the preparation step for the casing according to the second embodiment (part 3);

FIG. 15 is a perspective view of a casing included in a semiconductor device according to a third embodiment;

FIG. 16 illustrates assembling of a terminal body, the assembling being included in a preparation step for the casing according to the third embodiment;

FIGS. 17A and 17B illustrate terminals included in the terminal body according to the third embodiment;

FIG. 18 illustrates molding of a terminal unit with casing material, the molding being included in the preparation step for the casing according to the third embodiment;

FIG. 19 is a perspective view of a casing included in a semiconductor device according to a fourth embodiment;

FIG. 20 illustrates assembling of a terminal body, the assembling being included in a preparation step for the casing according to the fourth embodiment (part 1);

FIG. 21 illustrates assembling of the terminal body, the assembling being included in the preparation step for the casing according to the fourth embodiment (part 2);

FIG. 22 illustrates molding of a terminal unit with casing material, the molding being included in the preparation step for the casing according to the fourth embodiment (part 1); and

FIG. 23 illustrates molding of the terminal unit with casing material, the molding being included in the preparation step for the casing according to the fourth embodiment (part 2).

### DETAILED DESCRIPTION OF THE INVENTION

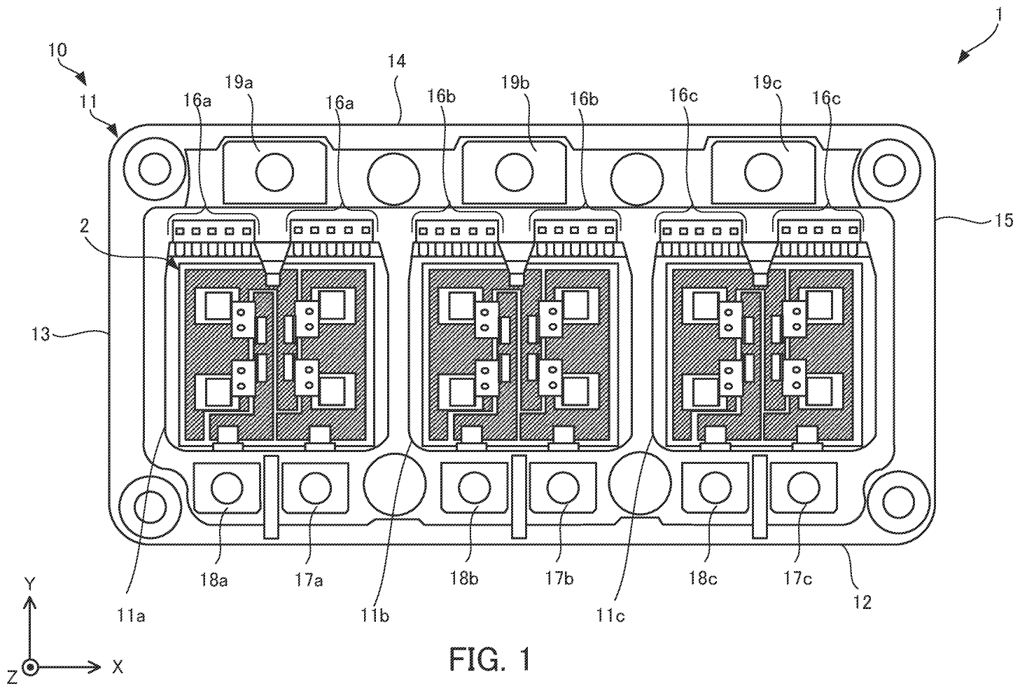

Hereinafter, embodiments will be described with reference to the accompanying drawings. In the following description, regarding a semiconductor device 1 in FIG. 1, terms “front surface” and “top surface” each express an X-Y surface facing upward (the +Z direction). Likewise, regarding the semiconductor device 1 in FIG. 1, a term “up” expresses the upper direction (the +Z direction). Regarding the semiconductor device 1 in FIG. 1, terms “rear surface” and “bottom surface” each express an X-Y surface facing downward (the −Z direction). Likewise, regarding the semiconductor device 1 in FIG. 1, a term “down” expresses the lower direction (the −Z direction). In all the other drawings, the above terms also mean their respective directions, as appropriate. In addition, regarding the semiconductor device 1 in FIG. 1, an expression “upper level” means an upper location (the +Z direction). Likewise, regarding the semiconductor device 1 in FIG. 1, an expression “lower level” means a lower location (the −Z direction). The terms “front surface”, “top surface”, “up”, “rear surface”, “bottom surface”, “down”, and “side surface” are simply used as convenient expressions to determine relative positional relationships and do not limit the technical ideas of the embodiments. For example, the terms “up” and “down” may mean directions other than the vertical directions with respect to the ground. That is, the directions expressed by “up” and “down” are not limited to the directions relating to the gravitational force. In addition, in the following description, when a component contained in material represents 80 vol % or more of the material, this component will be referred to as “main component” of the material. In addition, an expression “approximately the same” may be used when an error between two elements is within in ±10%. In addition, even when two elements are not exactly perpendicular, orthogonal, or parallel to each other, the two elements may be described as being “perpendicular”, “orthogonal”, or “parallel” to each other if the error is within ±10°. Hereinafter, the semiconductor device 1 will be described as an example of an electronic device. The semiconductor device 1 is only an example of an electronic device, and there are many other electronic devices, besides the semiconductor device 1.

### First Embodiment

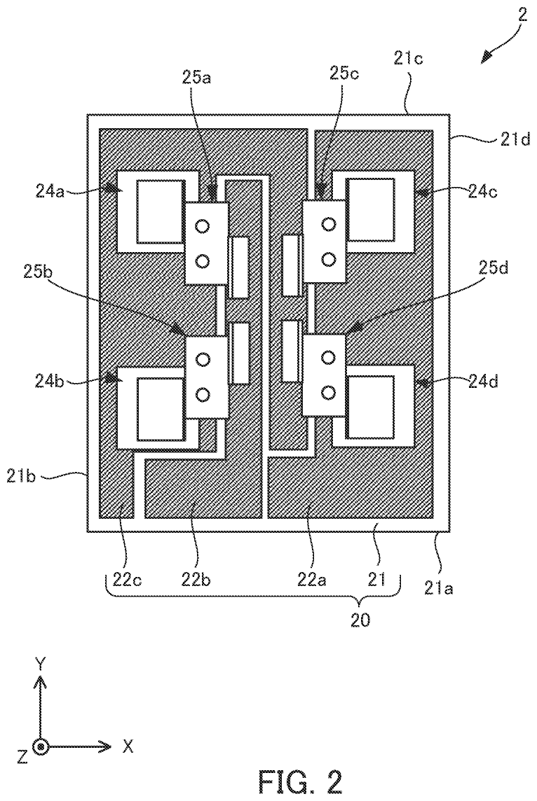

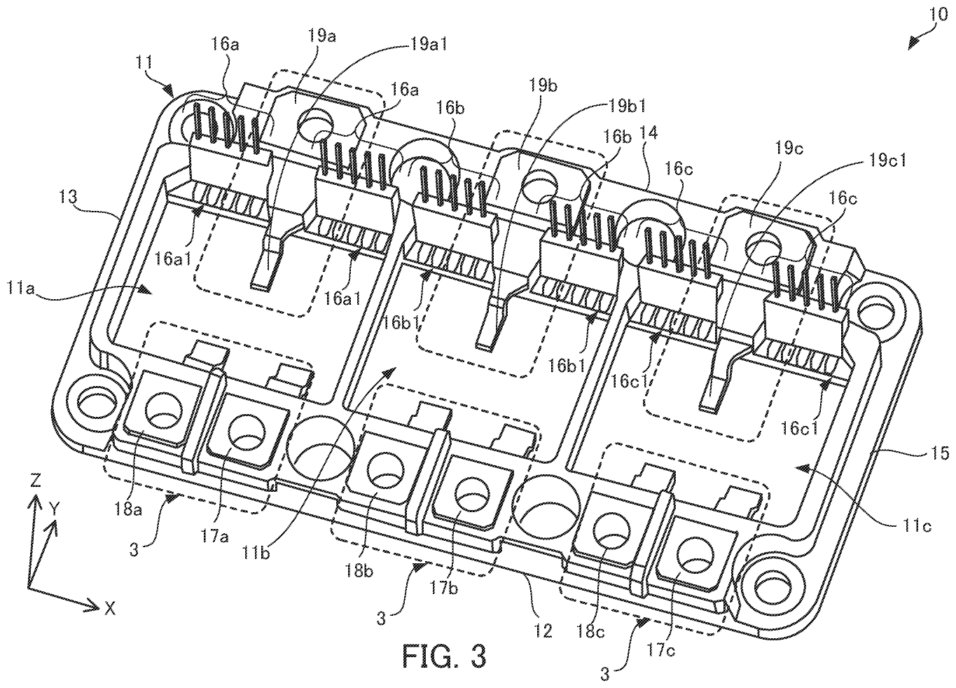

A semiconductor device according to a first embodiment will be described with reference to FIGS. 1 to 3. FIG. 1 is a plan view of a semiconductor device according to the first embodiment. FIG. 2 is a plan view of a semiconductor unit included in the semiconductor device according to the first embodiment. FIG. 3 is a perspective view of a casing included in the semiconductor device according to the first embodiment.

As illustrated in FIG. 1, the semiconductor device 1, which is an example of an electronic device, includes semiconductor units 2 and a casing 10 storing the semiconductor units 2. FIG. 1 illustrates an example in which three semiconductor units 2 are stored in their respective three storage portions 11a to 11c of the casing 10. Although the storage portions 11a to 11c storing their respective semiconductor units 2 are sealed with sealing material, the sealing material is not illustrated in FIG. 1.

As illustrated in FIG. 2, each of the semiconductor units 2 includes an insulating circuit board 20, semiconductor chips 24a to 24d, and lead frames 25a to 25d. The insulating circuit board 20 has a rectangular shape in plan view. The insulating circuit board 20 includes an insulating plate 21, a plurality of circuit pattern layers formed on the front surface of the insulating plate 21, and a metal plate (not illustrated) formed on the rear surface of the insulating plate 21. The plurality of circuit pattern layers includes a positive circuit pattern layer 22a, a negative circuit pattern layer 22b, and an output circuit pattern layer 22c. Hereinafter, when these layers are not particularly distinguished from each other, these layers will be referred to as circuit pattern layers. In plan view, the outline of the circuit pattern layers and the outline of the metal plate are smaller than that of the insulating plate 21 and are located inside the insulating plate 21. The shape, number, and size of the plurality of circuit pattern layers illustrated in FIG. 2 are only an example.

The insulating plate 21 has a rectangular shape in plan view. For example, the insulating plate 21 may have chamfered or rounded corners. The insulating plate 21 has outer surfaces in four directions, which are sequentially referred to as a short side surface 21a, a long side surface 21b, a short side surface 21c, and a long side surface 21d. This insulating plate 21 is made of a ceramic material having a high thermal conductivity. For example, the ceramic material contains aluminum oxide, aluminum nitride, or silicon nitride as its main component.

The metal plate has a rectangular shape in plan view. For example, the metal plate may have chamfered or rounded corners. The metal plate is smaller than the insulating plate 21 and is formed on the entire rear surface of the insulating plate 21, excepting the edge portions thereof. The metal plate contains a metal material having an excellent thermal conductivity as its main component. The metal material is, for example, copper, aluminum, or an alloy containing at least one of these kinds. The metal plate may be plated to improve its corrosion resistance. The material used for this plating is, for example, nickel, a nickel-phosphorus alloy, or a nickel-boron alloy.

The plurality of circuit pattern layers include, as described above, the positive circuit pattern layer 22a, the negative circuit pattern layer 22b, and the output circuit pattern layer 22c. The plurality of circuit pattern layers are formed on the entire front surface of the insulating plate 21, excepting the edge portions thereof. Preferably, in plan view, end portions of the plurality of circuit pattern layers, the end portions facing the outline of the insulating plate 21, overlap with end portions of the metal plate, the end portions facing the outline of the insulating plate 21.

The plurality of circuit pattern layers are each made of a metal material having an excellent electrical conductivity. The metal material, is, for example, copper, aluminum, or an alloy containing at least one of these kinds. The surface of each of the plurality of circuit pattern layers may be plated to improve its corrosion resistance. The material used for this plating is, for example, nickel, a nickel-phosphorus alloy, or a nickel-boron alloy. The thickness of each of the plurality of circuit pattern layers may be approximately the same as that of the metal plate.

In plan view, the positive circuit pattern layer 22a included in the plurality of circuit pattern layers has a reversed L shape, is located near the long side surface 21d of the insulating plate 21, and is formed to mainly face the long side surface 21d and the short side surface 21a of the insulating plate 21. The semiconductor chips 24d and 24c are linearly bonded to the positive circuit pattern layer 22a in the +Y direction (second direction).

In plan view, the negative circuit pattern layer 22b included in the plurality of circuit pattern layers has a reversed L shape, faces the short side surface 21a of the insulating plate 21, and is formed next to the positive circuit pattern layer 22a in the −X direction.

In plan view, the output circuit pattern layer 22c included in the plurality of circuit pattern layers has an approximately U shape, faces the long side surface 21b and the short side surface 21c of the insulating plate 21, and is formed to surround the negative circuit pattern layer 22b. The semiconductor chips 24a and 24b are linearly bonded to the output circuit pattern layer 22c in the +Y direction.

For example, a direct copper bonding (DCB) substrate or an active metal brazed (AMB) substrate may be used as the insulating circuit board 20 constructed as described above. The insulating circuit board 20 releases the heat generated by the semiconductor chips 24a to 24d by transferring the heat to the rear surface of the insulating circuit board 20 via the output circuit pattern layer 22c, the positive circuit pattern layer 22a, the insulating plate 21, and the metal plate.

The semiconductor chips 24a to 24d are each a power device made of silicon carbide. An example of the power device is a power metal-oxide-semiconductor field-effect transistor (MOSFET). Each of these semiconductor chips 24a to 24d has a drain electrode as an input electrode on its rear surface and has a gate electrode as a control electrode and a source electrode as an output electrode on its front surface.

Alternatively, the semiconductor chips 24a to 24d may each be a power device made of silicon. In this case, the power device is, for example, a reverse-conducting (RC)-insulated gate bipolar transistor (IGBT). The RC-IGBT is obtained by forming an IGBT, which is a switching element, and a free-wheeling diode (FWD), which is a diode element, on one chip. For example, each of these semiconductor chips 24a to 24d has a collector electrode as an input electrode on its rear surface and has a gate electrode as a control electrode and an emitter electrode as an output electrode on its front surface.

In either case, the semiconductor chips 24a and 24b are bonded to the output circuit pattern layer 22c, with their control electrodes (not illustrated) facing the long side surface 21b, and the semiconductor chips 24c and 24d are bonded to the positive circuit pattern layer 22a, with their control electrodes (not illustrated) facing the long side surface 21d.

According the to present embodiment, the semiconductor chips 24a and 24b and the semiconductor chips 24c and 24d are bonded to the output circuit pattern layer 22c and the positive circuit pattern layer 22a, respectively, via bonding material (not illustrated). The bonding material may be solder or sintered body. The solder may be lead-free solder containing a predetermined alloy as its main component. The sintered material used for the bonding based on sintering may be, for example, powder of silver, iron, copper, aluminum, titanium, nickel, tungsten, or molybdenum.

The lead frames 25a to 25d are each made of a metal material having an excellent electrical conductivity. This metal material is, for example, copper, aluminum, or an alloy containing at least one of these kinds. The surface of each of the lead frames 25a to 25d may be plated to improve its corrosion resistance. The material used for this plating is, for example, nickel, a nickel-phosphorus alloy, or a nickel-boron alloy. The lead frames 25a to 25d may each have a generally uniform thickness.

The lead frame 25c electrically connects the output electrode of the semiconductor chip 24c and the output circuit pattern layer 22c. The lead frame 25d electrically connects the output electrode of the semiconductor chip 24d and the output circuit pattern layer 22c. The lead frame 25a electrically connects the output electrode of the semiconductor chip 24a and the negative circuit pattern layer 22b. The lead frame 25b electrically connects the output electrode of the semiconductor chip 24b and the negative circuit pattern layer 22b. These lead frames 25a to 25d are bonded to the output electrodes of the semiconductor chips 24a to 24d via solder as the above-described bonding material. The lead frames 25a to 25d are bonded to the circuit pattern layers via the above-described bonding material. Alternatively, the lead frames 25a to 25d may be bonded to the circuit pattern layers by ultrasonic bonding.

As illustrated in FIG. 1, the casing 10 includes a frame portion 11, and P terminals 17a to 17c, N terminals 18a to 18c, and U, V, and W terminals 19a to 19c, all of which are formed integrally with the frame portion 11.

The frame portion 11 has a rectangular frame shape in plan view. The frame portion 11 has a long side portion 12, a short side portion 13, a long side portion 14, and a short side portion 15, which are sequentially formed at four sides thereof. The frame portion 11 has a center portion sequentially surrounded by the long side portion 12, the short side portion 13, the long side portion 14, and the short side portion 15. In this center portion, three storage portions 11a, 11b, and 11c are defined.

The storage portions 11a to 11c are aligned along the long side portions 12 and 14. The storage portions 11a to 11c each have a rectangular shape in plan view. A semiconductor unit 2 is stored in each of the storage portions 11a to 11c. Regarding the semiconductor units 2 stored in the storage portions 11a to 11c, the semiconductor chips 24a and 24c are located in the direction of the long side portion 14, and the semiconductor chips 24b and 24d are located in the direction of the long side portion 12.

Sealing material is injected into the storage portions 11a to 11c such that the semiconductor units 2 are sealed with the sealing material. The sealing material may be thermosetting resin. The thermosetting resin is, for example, epoxy resin, phenol resin, maleimide resin, or polyester resin. Preferably, the thermosetting resin is epoxy resin. In addition, filler may be added to the sealing material. The filler is an insulating ceramic material having a high thermal conductivity. The filler is, for example, silicon oxide, aluminum oxide, boron nitride, or aluminum nitride. The amount of the filler contained may be between 10 vol % and 70 vol % of the sealing material.

The casing 10 includes input terminals at the long side portion 12. The input terminals are the P terminals 17a to 17c and the N terminals 18a to 18c formed along the long side portion 12. The P terminals 17a to 17c and the N terminals 18a to 18c have external end portions (external connection portions), which are formed on the front surface of the long side portion 12 in the +X direction. The P terminals 17a to 17c and the N terminals 18a to 18c have internal end portions (internal connection portions), which are exposed to the outside on the inner wall of the storage portions 11a to 11c, the inner wall being near the long side portion 12, and which extend toward the long side portion 14. The P terminals 17a to 17c and the N terminals 18a to 18c will be described in detail below.

In addition, the casing 10 includes output terminals at the long side portion 14, which are located on the other side of the storage portions 11a to 11c, assuming that the long side portion 12 is one side of the storage portions 11a to 11c. Specifically, the output terminals are the U, V, and W terminals 19a to 19c formed along the long side portion 14. The U, V, and W terminals 19a to 19c have external end portions (external connection portions), which are formed on the front surface of the long side portion 14 in the +X direction. The U, V, and W terminals 19a to 19c have internal connection portions 19a1 to 19c1, which are internal end portions and are exposed to the outside on the inner wall of the storage portions 11a to 11c, the inner wall being near the long side portion 14, and which extend toward the long side portion 12.

In addition, the casing addition, 10 includes control terminals 16a to 16c and control wiring plates 16a1 to 16c1, which are formed on the inner wall of the long side portion 14, the inner wall being near the storage portions 11a to 11c. For example, the control terminals 16a and the control wiring plates 16a1 are formed on the inner wall of the long side portion 14, the inner wall being near the storage portion 11a. The internal connection portion 19a1 of the U terminal 19a is sandwiched by one set of control terminals 16a and a control wiring plate 16a1 and the other set of control terminals 16a and a control wiring plate 16a1. The upper end of each control terminal 16a extends in the +Z direction. Each control wiring plate 16a1 includes wiring plates electrically connected to their respective control terminals 16a and an insulating plate on which the wiring plates are formed. Each control wiring plate 16a1 is formed to vertically extend from the inner wall of the long side portion 14, the inner wall being near the storage portion 11a. The lower end of each control terminal 16a is connected to a corresponding control wiring plate 16a1 in the long side portion 14. The wiring plates of each control wiring plate 16a1 are directly connected to the control electrodes of the semiconductor chips 24a to 24d included in the semiconductor unit 2 stored in the storage portion 11a via wires. Control signals inputted to the control terminals 16a are inputted to the control electrodes of the semiconductor chips 24a to 24d via the control wiring plates 16a1 and the wires.

The control terminals 16b and the control wiring plates 16b1 are also formed on the inner side of the long side portion 14, the inner side being near the storage portion 11b. The internal connection portion 19b1 of the V terminal 19b is sandwiched by one set of control terminals 16b and a control wiring plate 16b1 and the other set of control terminals 16b and a control wiring plate 16b1. Likewise, the control terminals 16c and the control wiring plates 16c1 are formed on the inner side of the long side portion 14, the inner side being near the storage portion 11c. The internal connection portion 19c1 of the W terminal 19c is sandwiched by one set of control terminals 16c and a control wiring plate 16c1 and the other set of control terminals 16c and a control wiring plate 16c1.

The P terminals 17a to 17c, the N terminals 18a to 18c, the U, V, and W terminals 19a to 19c, and the control terminals 16a to 16c are each made of a metal material having an excellent electrical conductivity. The metal material, is, for example, copper, aluminum, or an alloy containing at least one of these kinds. The surface of each of these terminals may be plated to improve its corrosion resistance. The material used for this plating is, for example, nickel, a nickel-phosphorus alloy, or a nickel-boron alloy. In addition, the wiring plates of the control wiring plates 16a1 to 16c1 are each made of a metal material having an excellent electrical conductivity. The metal material, is, for example, copper, aluminum, or an alloy containing at least one of these kinds.

The long side portion 12 of the casing 10 integrally includes terminal units 3 (dashed areas at the long side portion 12 in FIG. 3), each of which is formed for one of the storage portions 11a to 11c. Each terminal unit 3 include a corresponding one of the P terminals 17a to 17c and a corresponding one of the N terminals 18a to 18c. The terminal units 3 will be described in detail below. Likewise, the long side portion 14 of the casing 10 integrally includes terminal units (reference numerals are not illustrated) (dashed areas at the long side portion 14 in FIG. 3), each of which is formed for one of the storage portions 11a to 11c. Each terminal unit includes a corresponding one of the U, V, and W terminals 19a to 19c.

Although not illustrated, a heatsink having approximately the same size as that of the casing 10 is formed on the rear surface of the casing 10. This heatsink is made of a metal material having an excellent electrical conductivity as its main component. The metal material is, for example, copper, aluminum, or an alloy containing at least one of these kinds. The metal plate may be plated to improve its corrosion resistance. The material used for this plating is, for example, nickel, a nickel-phosphorus alloy, or a nickel-boron alloy. The semiconductor units 2 are formed on this heatsink, and the casing 10 is disposed on this heatsink such that the semiconductor units 2 are stored in the storage portions 11a to 11c.

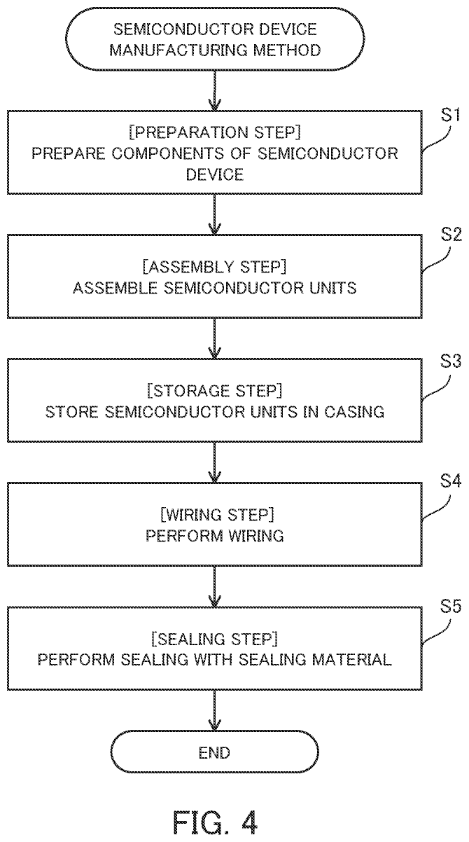

Next, a manufacturing method of the semiconductor device 1 will be described with reference to FIG. 4. FIG. 4 is a flowchart illustrating a manufacturing method of the semiconductor device according to the first embodiment. First, a preparation step of preparing the components of the semiconductor device 1 is performed (step S1). The components prepared in this preparation step are, for example, the insulating circuit boards 20, the casing 10, the semiconductor chips 24a to 24d, and the lead frames 25a to 25d. All the other components needed to manufacture the semiconductor device 1 are also prepared. In addition, a manufacturing apparatus used for manufacturing the semiconductor device 1 may also be prepared.

Next, an assembly step of assembling the semiconductor units 2 is performed (step S2). The semiconductor chips 24c and 24d are disposed on the positive circuit pattern layer 22a of each insulating circuit board 20 via the above-described bonding material, and the semiconductor chips 24a and 24b are disposed on the output circuit pattern layer 22c of each insulating circuit board 20 via the above-described bonding material. By heating and melting the bonding material, the semiconductor chips 24c and 24d are bonded to the positive circuit pattern layer 22a, and the semiconductor chips 24a and 24b are bonded to the output circuit pattern layer 22c. In addition, one end portion of each of the lead frames 25a to 25d is disposed on the output electrode of a corresponding one of the semiconductor chips 24a to 24d via the above-described bonding material. The other end portion of each of the lead frames 25a and 25b is disposed on the negative circuit pattern layer 22b via the above-described bonding material, and the other end portion of each of the lead frames 25c and 25d is disposed on the output circuit pattern layer 22c via the above-described bonding material. By heating and melting the bonding material, the lead frames 25a and 25b are bonded to the semiconductor chips 24a and 24b and the negative circuit pattern layer 22b, and the lead frames 25c and 25d are bonded to the semiconductor chips 24c and 24d and the output circuit pattern layer 22c.

Next, a storage step of storing the semiconductor units 2 in the storage portions 11a to 11c of the casing 10 is performed (step S3). The semiconductor units 2 are disposed at predetermined locations of the heatsink, and the casing 10 is disposed on the heatsink such that the semiconductor units 2 are stored in the storage portions 11a, 11b, and 11c of the casing 10.

A wiring step of performing wiring on the semiconductor units 2 is performed (step S4). In this wiring step, for example, an internal connection portion 17a3, which will be described below, of the P terminal 17a is bonded to the positive circuit pattern layer 22a of the semiconductor unit 2 stored in the storage portion 11a. In addition, an internal connection portion 18a3, which will be described below, of the N terminal 18a, is bonded to the negative circuit pattern layer 22b of the semiconductor unit 2 stored in the storage portion 11a. In addition, the internal connection portion 19a1 of the U terminal 19a is bonded to the output circuit pattern layer 22c of the semiconductor unit 2. For example, ultrasonic bonding may be used for the bonding. The P terminals 17b and 17c, the N terminals 18b and 18c, the V and W terminals 19b and 19c are also bonded in the same way to their respective semiconductor units 2 stored in the storage portions 11b and 11c. In addition, the control wiring plates 16a1 to 16c1 are connected to the control electrodes of the semiconductor chips 24a to 24d via the above-described wires.

Next, a sealing step of sealing the semiconductor units 2 with the above-described sealing material is performed (step S5). The sealing material is injected into the storage portions 11a to 11c in which the semiconductor units 2 are stored. In this sealing step, the sealing material is injected until the semiconductor units 2 and the wires connected to the control electrodes are completely embedded in the sealing material. When the injected sealing material is solidified, the sealing of the semiconductor units 2 in the storage portions 11a to 11c is completed. In this way, the semiconductor device 1 illustrated in FIG. 1 is manufactured.

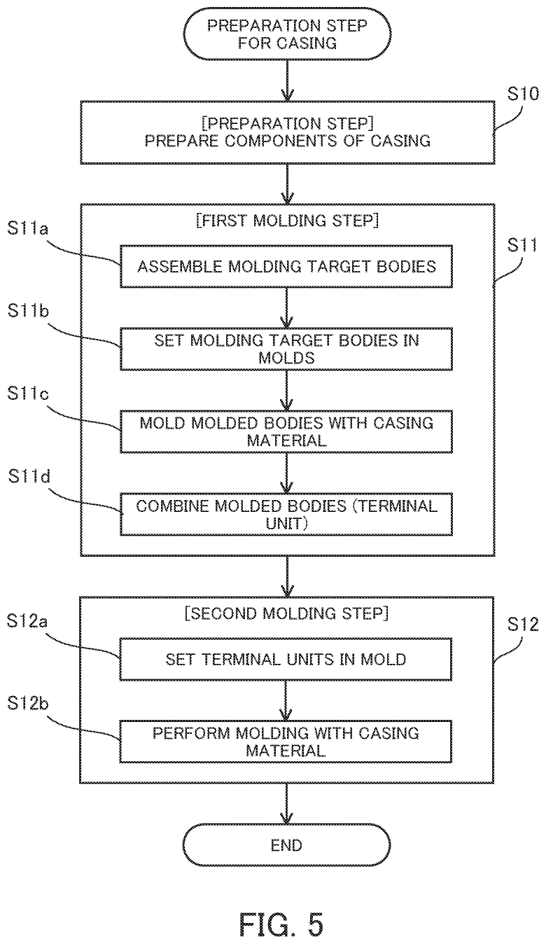

Next, a preparation step for the casing 10 prepared in the above preparation step will be described with reference to FIG. 5. FIG. 5 is a flowchart illustrating a preparation step for the casing of the semiconductor device according to the first embodiment. The casing 10 of the semiconductor device 1 is prepared (manufactured) through the following steps.

First, a preparation step of preparing the components of the casing 10 is performed (step S10). The components of the casing 10 are, for example, the casing material of the casing 10, the P terminals 17a to 17c, the N terminals 18a to 18c, the U, V, and W terminals 19a to 19c, and the control terminals 16a to 16c. All the other components needed to manufacture the casing 10 are also prepared. In addition, a manufacturing apparatus used for manufacturing the casing 10 may also be prepared. A mold for molding the individual terminal unit 3, which will be described below, and a mold for molding the casing 10 are also prepared.

The casing material prepared in this step contains thermoplastic resin as its main component. The casing material may contain filler as release agent. Examples of the thermoplastic resin include polyphenylene sulfide resin, polybutylene terephthalate resin, polybutylene succinate resin, polyamide resin, and acrylonitrile butadiene styrene resin. The filler is, for example, silicon oxide, aluminum oxide, boron nitride, or aluminum nitride. That is, this casing material is the main component of the frame portion 11 including the terminal units 3.

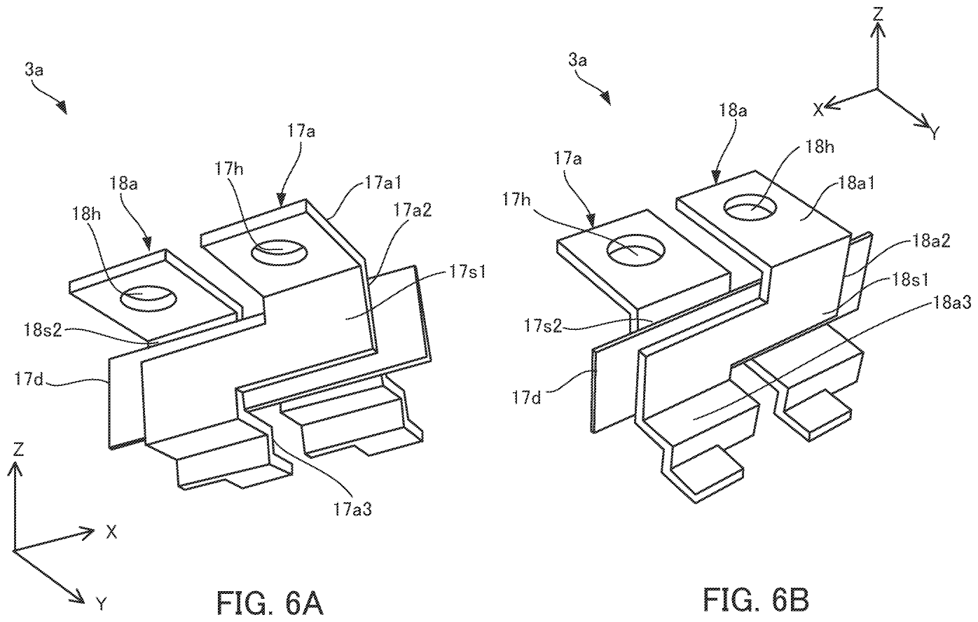

Next, a first molding step of molding the terminal units 3 is performed (step S11). The first molding step includes the following four steps. First, molding target bodies are assembled (step S11a). Terminal bodies, which are the assembled molding target bodies, will be described with reference to FIGS. 6A and 6B. FIGS. 6A and 6B illustrate assembling of a terminal body, the assembling being included in the preparation step for the casing according to the first embodiment. FIG. 6A is a perspective view of a terminal body 3a viewed from one side, and FIG. 6B is a perspective view of the terminal body 3a viewed from the other side. Even when the terminal body 3a includes the N terminal 18b, an insulating sheet 17d, and the P terminal 17b or includes the N terminal 18c, an insulating sheet 17d, and the P terminal 17c, the terminal body 3a has the same perspective views a those illustrated in FIGS. 6A and 6B.

In FIGS. 6A and 6B, the terminal body 3a includes the P terminal 17a, an insulating sheet 17d, and the N terminal 18a. The P terminal 17a (a first terminal) includes an external connection portion 17a1 (a first external end portion), a wiring portion 17a2 (a first center portion), and the internal connection portion 17a3 (a first internal end portion). The external connection portion 17a1 has a rectangular flat plate shape in plan view. The external connection portion 17a1 has a fastening hole 17h, which penetrates through the external connection portion 17a1.

The wiring portion 17a2 has a rectangular flat plate shape in plan view with first and second long sides in the ±X direction and includes an outer surface 17s1 and an opposing surface 17s2, which is the side opposite to the outer surface 17s1. The wiring portion 17a2 extends in the +X direction. The external connection portion 17a1 is formed integrally with a +X direction end portion of a +Z direction long side of the wiring portion 17a2. Furthermore, the P terminal 17a is bent at the connecting portion between the external connection portion 17a1 and the wiring portion 17a2. More specifically, the external connection portion 17a1 is tilted about the connecting portion toward the outer surface 17s1 of the wiring portion 17a2. The external connection portion 17a1 extends approximately perpendicularly to the wiring portion 17a2.

The internal connection portion 17a3 has a rectangular flat plate shape in plan view. The internal connection portion 17a3 may have a step portion. The internal connection portion 17a3 is bonded to a circuit pattern layer of a semiconductor unit 2. The internal connection portion 17a3 is formed integrally with a −X direction end portion of a −Z direction long side of the wiring portion 17a2. The P terminal 17a is bent at the connecting portion between the wiring portion 17a2 and the internal connection portion 17a3. More specifically, the internal connection portion 17a3 is tilted about the connecting portion toward the opposing surface 17s2, which is the side opposite to the outer surface 17s1 of the wiring portion 17a2. That is, the internal connection portion 17a3 is tilted about the connecting point in the opposite direction of the external connection portion 17a1. The internal connection portion 17a3 extends approximately perpendicularly to the wiring portion 17a2. As shown in FIGS. 6A and 6B, one end portion of the first long side of the outer surface 17s1 and one end portion of the second long side of the outer surface 17s1 are located diagonally opposite to each other with respect to the rectangular shape of the wiring portion 17a2.

The N terminal 18a (a second terminal) includes an external connection portion 18a1 (a second external end portion), a wiring portion 18a2 (a second center portion), and the internal connection portion 18a3 (a second internal end portion). The external connection portion 18a1 has a rectangular flat plate shape in plan view. The external connection portion 18a1 has a fastening hole 18h, which penetrates through the external connection portion 18a1.

The wiring portion 18a2 has a rectangular flat plate shape in plan view with first and second long sides in the ±X direction and includes an outer surface 18s1 and an opposing surface 18s2, which is the side opposite to the outer surface 18s1. The wiring portion 18a2 extends in the +X direction. The external connection portion 18a1 is formed integrally with a −X direction end portion of a +Z direction long side of the wiring portion 18a2. The N terminal 18a is bent at the connecting portion between the external connection portion 18a1 and the wiring portion 18a2. More specifically, the external connection portion 18a1 is tilted about the connecting portion toward the opposing surface 18s2 of the wiring portion 18a2. The external connection portion 18a1 extends approximately perpendicularly to the wiring portion 18a2.

The internal connection portion 18a3 has a rectangular flat plate shape in plan view. The internal connection portion 18a3 may have a step portion. The internal connection portion 18a3 is bonded to a circuit pattern layer of the semiconductor unit 2. The internal connection portion 18a3 is formed integrally with a +X direction end portion of a −Z direction long side of the wiring portion 18a2. The N terminal 18a is bent at the connecting portion between the wiring portion 18a2 and the internal connection portion 18a3. More specifically, the internal connection portion 18a3 is tilted about the connecting portion toward the outer surface 18s1, which is the side opposite to the opposing surface 18s2 of the wiring portion 18a2. That is, the internal connection portion 18a3 is tilted about the connecting portion in the opposite direction of the external connection portion 18a1. The internal connection portion 18a3 extends approximately perpendicularly to the wiring portion 18a2. As shown in FIGS. 6A and 6B, one end portion of the first long side of the outer surface 18s1 and one end portion of the second long side of the outer surface 18s1 are located diagonally opposite to each other with respect to the rectangular shape of the wiring portion 18a2.

The insulating sheet 17d has a rectangular shape as seen in ±Y direction in FIGS. 6A and 6B. The area of the insulating sheet 17d is sufficiently larger than that of each of the wiring portions 17a2 and 18a2. The insulating sheet 17d is sandwiched by the opposing surface 17s2 of the wiring portion 17a2 included in the P terminal 17a and the opposing surface 18s2 of the wiring portion 18a2 included in the N terminal 18a. That is, the area of the insulating sheet 17d is not limited to a particular area, as long as the insulation between the P terminal 17a and the N terminal 18a is maintained when the insulating sheet 17d is sandwiched by the opposing surface 17s2 of the wiring portion 17a2 included in the P terminal 17a and the opposing surface 18s2 of the wiring portion 18a2 included in the N terminal 18a. The insulating sheet 17d may be a sheet-like insulating member, examples of which include an insulating paper and film.

It is possible to assemble another terminal body 3a in the same way by using the P and N terminals 17b and 18b or the P and N terminals 17c and 18c and the insulating sheet 17d. That is, each of the P terminals 17b and 17c also includes the external connection portion 17a1 (the first external end portion), the wiring portion 17a2 (the first center portion), and the internal connection portion 17a3 (the first internal end portion). Each of the N terminals 18b and 18c also includes the external connection portion 18a1 (the second external end portion), the wiring portion 18a2 (the second center portion), and the internal connection portion 18a3 (the second internal end portion).

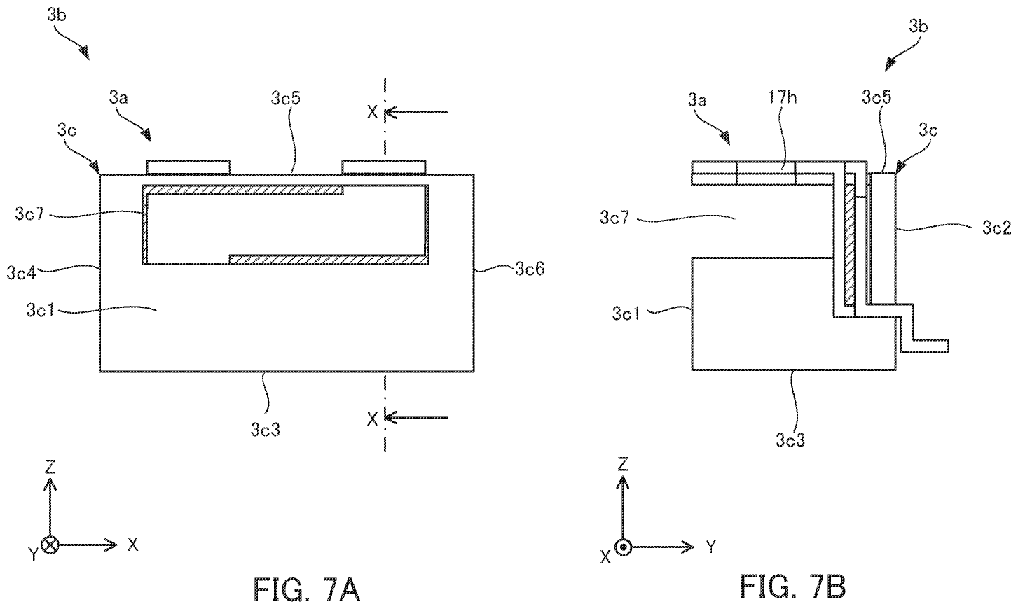

Next, the three assembled terminal bodies 3a, which are molding target bodies, are each set in a predetermined mold (step S11b). Next, the casing material is injected into the molds, so as to mold molded bodies (step S11c). A terminal-embedded body 3b, which is a molded body, will be described with reference to FIGS. 7A and 7B. FIGS. 7A and 7B each illustrate molding of a terminal-embedded body with casing material, the molding being included in the preparation step for the casing according to the first embodiment. FIG. 7A is a side view of a terminal-embedded body 3b viewed in the +Y direction, and FIG. 7B is a sectional view taken along a dashed-dotted line X-X in FIG. 7A.

The terminal-embedded body 3b includes a terminal body 3a and a terminal main body 3c that seals the terminal body 3a. The terminal main body 3c is a specific example of a first resin portion and has a cuboid shape. That is, the terminal main body 3c has a rectangular top surface 3c5 and a rectangular top bottom surface 3c3 in plan view. The bottom surface 3c3 has the same shape and size as those of the top surface 3c5 and is located on the side opposite to the top surface 3c5. In addition, the terminal main body 3c includes a front surface 3c1, a side surface 3c4, a back surface 3c2, and a side surface 3c6 that sequentially surround the top surface 3c5 and the bottom surface 3c3 in plan view. The front surface 3c1 and the back surface 3c2 are located opposite each other and have the same size. The side surfaces 3c4 and 3c6 are located opposite each other and has the same size. The length of the front surface 3c1 and the back surface 3c2 in the ±X directions is longer than that of the terminal body 3a. That is, the ±X direction end portions of the terminal body 3a are completely sealed by the terminal main body 3c.

The external connection portions 17a1 and 18a1 of the P and N terminals 17a and 18a protrude from the top surface 3c5 of the terminal main body 3c in the +Z direction and are tilted toward the front surface 3c1. Thus, the external connection portions 17a1 and 18a1 of the P and N terminals 17a and 18a face the top surface 3c5 and extend in the −Y direction (first direction). The top surface 3c5 of the terminal main body 3c has through holes at the areas matching the fastening holes 17h and 18h in the external connection portions 17a1 and 18a1 of the P and N terminals 17a and 18a. The through holes have the same shape and size as those of the fastening holes 17h and 18h. The internal connection portions 17a3 and 18a3 of the P and N terminals 17a and 18a included in the terminal body 3a protrude from the back surface 3c2 of the terminal main body 3c in the +Y direction.

In addition, a storage portion 3c7 is formed at the front surface 3c1 of the terminal main body 3c. The storage portion 3c7 has a cuboid shape. The storage portion 3c7 may have any shape and size as long as a nut-embedded body 3d, which will described below, is storable in the storage portion 3c7. In the storage portion 3c7, the outer surface 17s1 of the P terminal 17a of the sealed terminal body 3a is partly exposed to the outside when seen from the direction of the front surface 3c1.

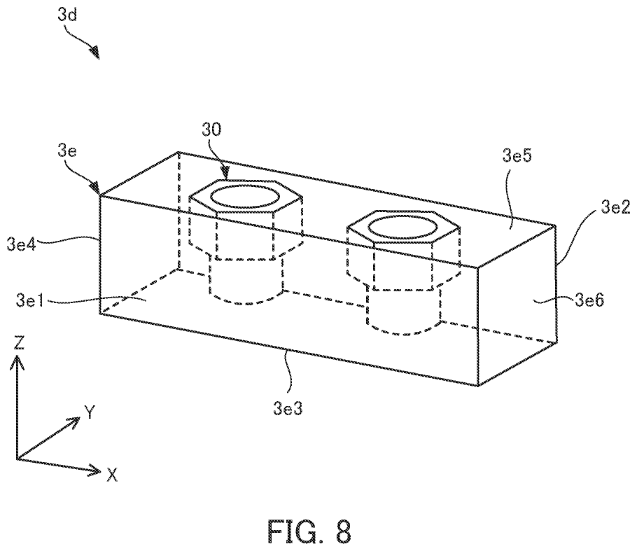

According to the first embodiment, nut-embedded bodies, which are another kind of molded bodies, are also molded. That is, in this case, nuts 30, which are molding target bodies, are set in another kind of predetermined molds (step S11b). Next, casing material is injected into the molds, to mold the individual nut-embedded bodies (step S11c). These nut terminal bodies, which are molded bodies, will be described with reference to FIG. 8. FIG. 8 illustrates molding of a nut-embedded body with casing material, the molding being included in the preparation step for the casing according to the first embodiment.

This nut-embedded body 3d includes nuts 30 and a nut main body 3e that seals the nuts 30. Each of the nuts 30 has a fastening hole having a diameter that matches a screw to be installed into the fastening hole. The fastening holes 17h and 18h of the external connection portions 17a1 and 18a1 of the P and N terminals 17a and 18a each have a diameter that matches the fastening hole of the corresponding nut 30.

The casing material that constitutes the nut main body 3e is the same as the casing material that constitutes the terminal main body 3c. The nut main body 3e has a cuboid shape that matches the storage portion 3c7 of the terminal main body 3c. That is, the nut main body 3e has a rectangular top surface 3e5 and a rectangular bottom surface 3e3 in plan view. The bottom surface 3e3 has the same shape and size as those of the top surface 3e5 and is located on the side opposite to the top surface 3e5. In addition, the nut main body 3e has a front surface 3e1, a side surface 3e4, a back surface 3e2, and a side surface 3e6, which sequentially surround the top surface 3e5 and the bottom surface 3e3 in plan view. The front surface 3e1 and the back surface 3e2 are located opposite each other and have the same size. The side surfaces 3e4 and 3e6 are located opposite each other and have the same size. The nuts 30 are embedded in the top surface 3e5 of the nut main body 3e. The principal surface of each nut 30 and the top surface 3e5 are on the same plane. Alternatively, the principal surface of each nut 30 may be located lower than the top surface 3e5.

Although not described in detail herein, the terminal units of the casing 10, each of which is surrounded by a dashed line in FIG. 3 and includes a corresponding one of the U, V, and W terminals 19a, 19b, and 19c, may also be molded in accordance with steps S11b and S11c.

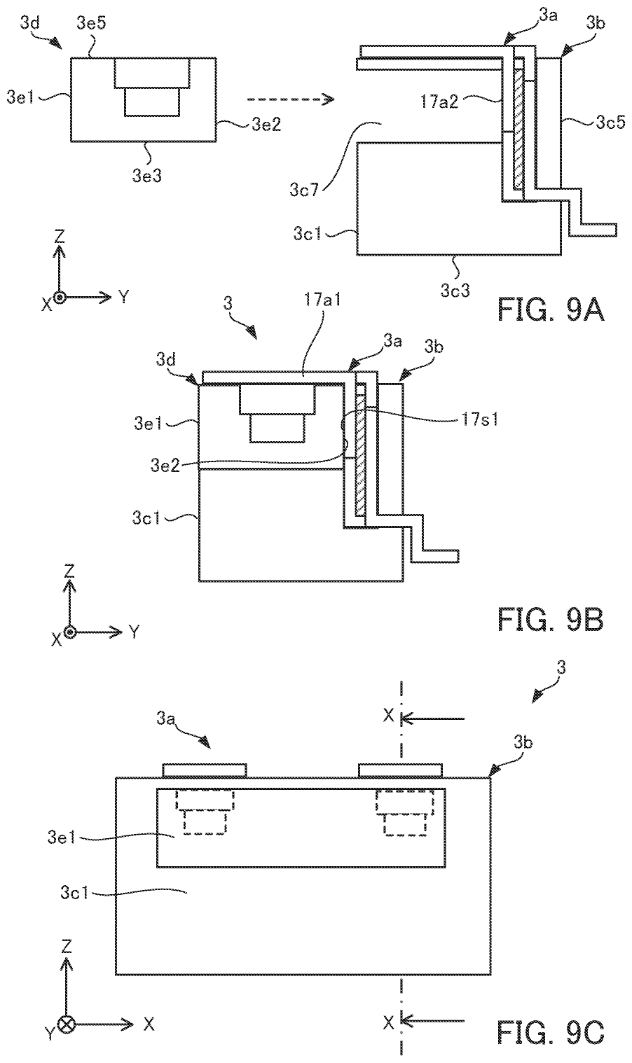

Next, two molded bodies (a terminal-embedded body 3b and a nut-embedded body 3d) molded as described above are combined with each other (step S11d). The combining of the two molded bodies (the terminal-embedded body 3b and the nut-embedded body 3d) will be described with reference to FIGS. 9A to 9C. FIGS. 9A to 9C illustrate combining of molded bodies, the combining being included in the preparation step for the casing according to the first embodiment. FIG. 9A is a sectional side view illustrating attachment of a nut-embedded body 3d to a terminal-embedded body 3b. FIG. 9B is a sectional view taken along a dashed-dotted line X-X in FIG. 9C. FIG. 9C is a front view of the terminal unit 3.

As illustrated in FIG. 9A, the nut-embedded body 3d is inserted into the storage portion 3c7 of the terminal-embedded body 3b such that the top surface 3e5 faces upward. The terminal unit 3 is assembled by inserting the nut-embedded body 3d into the storage portion 3c7 of the terminal-embedded body 3b.

With this terminal unit 3, as illustrated in FIG. 9B, the back surface 3e2 of the nut-embedded body 3d stored in the storage portion 3c7 is in contact with the outer surface 17s1 of the wiring portion 17a2 of the P terminal 17a. In FIGS. 9A to 9C, each of the fastening holes 17h and 18h in the external connection portions 17a1 and 18a1 of the P and N terminals 17a and 18a matches a nut 30 included in the nut-embedded body 3d. In addition, as illustrated in FIG. 9C, the front surface 3e1 of the nut-embedded body 3d and the front surface 3c1 of the terminal-embedded body 3b are on the same plane.

Next, a second molding step of molding the casing 10 is performed (step S12). The second molding step includes the following two steps. First, to mold the casing 10, the terminal units 3 are set in a predetermined mold (step S12a). The terminal units 3 molded in the first molding step are set in a predetermined mold for molding the casing 10. In this step, the terminal units 3 are set in locations of the mold, the locations corresponding to the terminal units 3 in FIG. 3, along with the control terminals 16a to 16c, the control wiring plates 16a1 to 16c1, and the U, V, and W terminals 19a to 19c. If the terminal units including the U, V, and W terminals 19a to 19c have already been molded, these terminal units are also set in the mold.

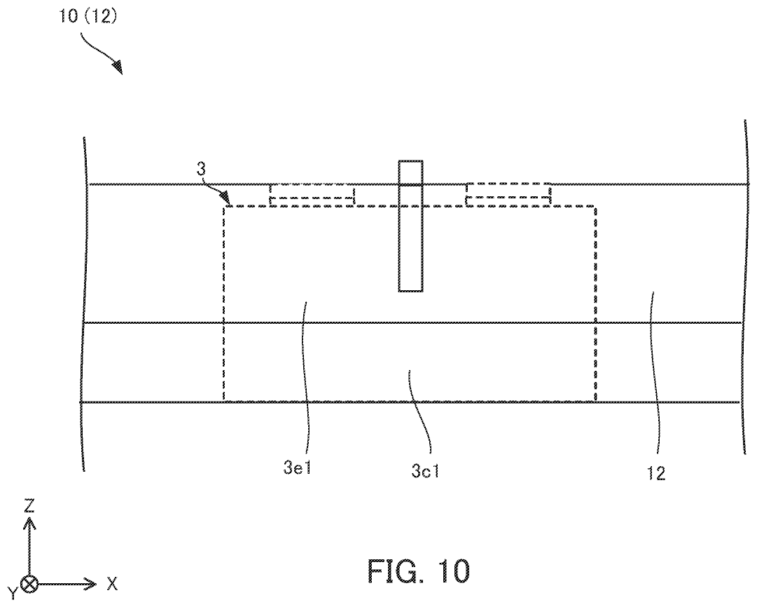

Next, casing material is injected into the mold including the terminal units 3, so as to mold the casing 10 (step S12b). Main portions of the casing 10, which is molded with casing material and is a specific example of a second resin portion, will be described with reference to FIG. 10. FIG. 10 illustrates the second molding step included in the preparation step for the casing according to the first embodiment. FIG. 10 is a side view in which main portions of the casing 10, the main portions corresponding to the P and N terminals 17a and 18a, are viewed in the +Y direction.

When casing material is injected into the mold in which the terminal units 3, etc., are set, the casing material flows inside the mold. Since the individual terminal unit 3 has a cuboid shape, the casing material easily flows around the terminal units 3 without leaving any space. Thus, the casing material flowing inside the mold is able to flow all around the terminal units 3 while preventing occurrence of voids.

As illustrated in FIG. 10, the terminal unit 3 including the P and N terminals 17a and 18a is integrally included in the long side portion 12 of the casing 10 formed as described above with the injected casing material. The casing material may seal the top surface 3c5 of the terminal unit 3, as needed. In the same way, the terminal unit 3 including the P and N terminals 17b and 18b and the terminal unit 3 including the P and N terminals 17c and 18c are integrally included in the long side portion 12 of the casing 10. In addition, in the same way, the terminal units including the U, V, and W terminals 19a, 19b, and 19c are integrally included in the long side portion 14 of the casing 10.

The casing 10 is molded as described above. The casing 10 molded as described is prepared in step S1 of the flowchart in FIG. 4, and the semiconductor device 1 is manufactured through steps S2 to S5.

Next, another manufacturing method in which the casing 10 is directly molded without molding the terminal units 3 will be described. In this case, the individual terminal bodies 3a, the U, V, and W terminals 19a to 19c, the control terminals 16a to 16c, the control wiring plates 16a1 to 16c1 are set in a mold. Casing material is injected into the mold in which the above-described components are set. The casing material, which has been injected into the mold, seals the components inside the mold. However, as illustrated in FIGS. 6A and 6B, for example, the individual terminal body 3a includes the P terminal 17a, the insulating sheet 17d, and the N terminal 18a. In particular, the insulating sheet 17d is sandwiched by the wiring portion 17a2 of the P terminal 17a and the wiring portion 18a2 of the N terminal 18a. That is, for example, a step portion, a corner portion, a groove portion, and a gap are formed by the P terminal 17a, the insulating sheet 17d, and the N terminal 18a of the terminal body 3a. When the terminal body 3a having this structure is sealed with the casing material in the mold, it is difficult for the casing material to sufficiently flow around the terminal body 3a due to the viscosity and fluidity of the casing material. Thus, even if the terminal body 3a is sealed with the casing material, voids could be formed inside. In addition, if the individual terminal body 3a described above is set in the mold, weld lines (voids) easily occur at locations where the casing material injected from an injection port flows and converges in the mold. These voids included in the casing 10 molded as described above deteriorate the strength and the dielectric strength of the casing 10. A semiconductor device including this casing 10 has a low reliability.

In addition, if the casing 10 of a large size is molded, a mold of a large size is needed. The temperature of the casing material injected into this mold differs depending on the location of the casing material in the mold. Thus, warping occurs in the molded casing 10. In addition, warping could occur in the casing 10, depending on the thickness of the casing 10. The warping of the casing 10 results in defective dimensions of the casing 10.

To prevent the above-described deterioration in moldability and quality of the casing 10, flow analysis of the casing material with respect to the mold may be performed. It is possible to manufacture a mold that is able to mold the casing 10 that prevents occurrence of voids, welds, and warps as much as possible, based on the analysis result. In reality, to manufacture this mold, flow analysis of the casing material with respect to a prototype of the mold is performed, and the result of the flow analysis is fed back each time a prototype is created such that an accurate mold is manufactured. Although it is possible to manufacture a mold that molds the casing 10 that prevents quality deterioration, a large cost is needed to manufacture this mold.

The above-described semiconductor device 1 includes the casing 10. The casing 10 includes the terminal main bodies 3c, the P terminals 17a to 17c, the N terminals 18a to 18c, the insulating sheets 17d, and the frame portion 11. Each of the P terminals 17a to 17c includes the wiring portion 17a2 that is in contact with the corresponding terminal main body 3c, the external connection portion 17a1 that is exposed to the outside at least partly from the terminal main body 3c and that extends from the wiring portion 17a2 such as to form a bend therebetween, and the internal connection portion 17a3 that extends from the wiring portion 17a2 such as to form a bend therebetween in the opposite direction of the external connection portion 17a1. Each of the N terminals 18a to 18c includes the wiring portion 18a2 that is disposed to face the wiring portion 17a2 and that is in contact with the terminal main body 3c, the external connection portion 18a1 that is exposed to the outside at least partly from the terminal main body 3c and that extends from the wiring portion 18a2 such as to form a bend therebetween in the same direction as the external connection portion 17a1, and the internal connection portion 18a3 that extends from the wiring portion 18a2 such as to form a bend in the opposite direction of the external connection portion 18a1. The insulating sheet 17d is disposed between the wiring portions 17a2 and 18a2. The frame portion 11 holds at least one of the terminal main bodies 3c, the wiring portions 17a2 and 18a2, and the insulating sheets 17d. Thus, occurrence of voids and welds in the frame portion 11 is prevented, and occurrence of warping is also prevented. Thus, the moldability of the casing 10 is improved, and the frame portion 11 having sufficient quality is formed. In addition, deterioration in the reliability of the semiconductor device 1 including this casing 10 is prevented.

### Second Embodiment

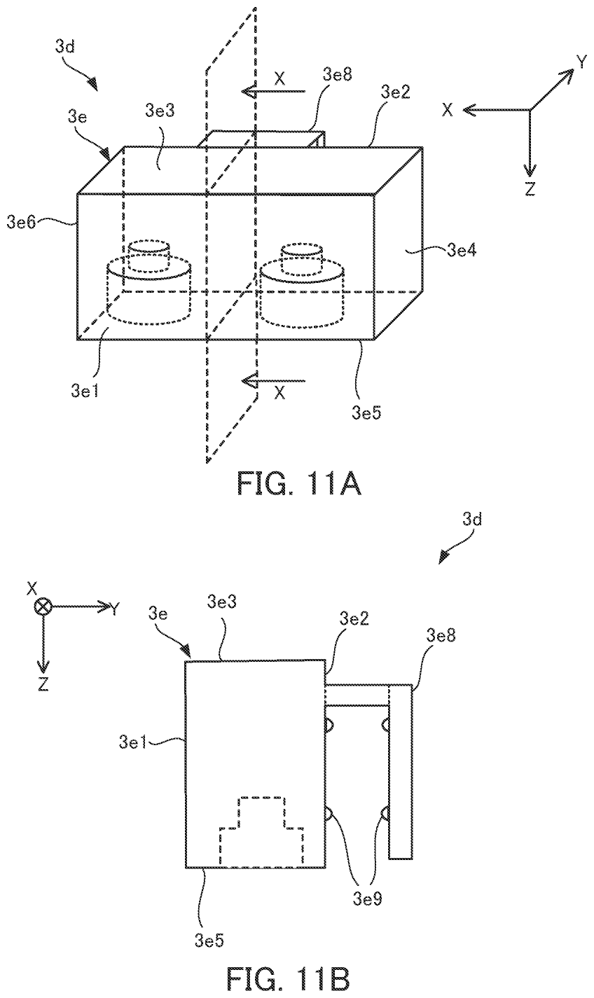

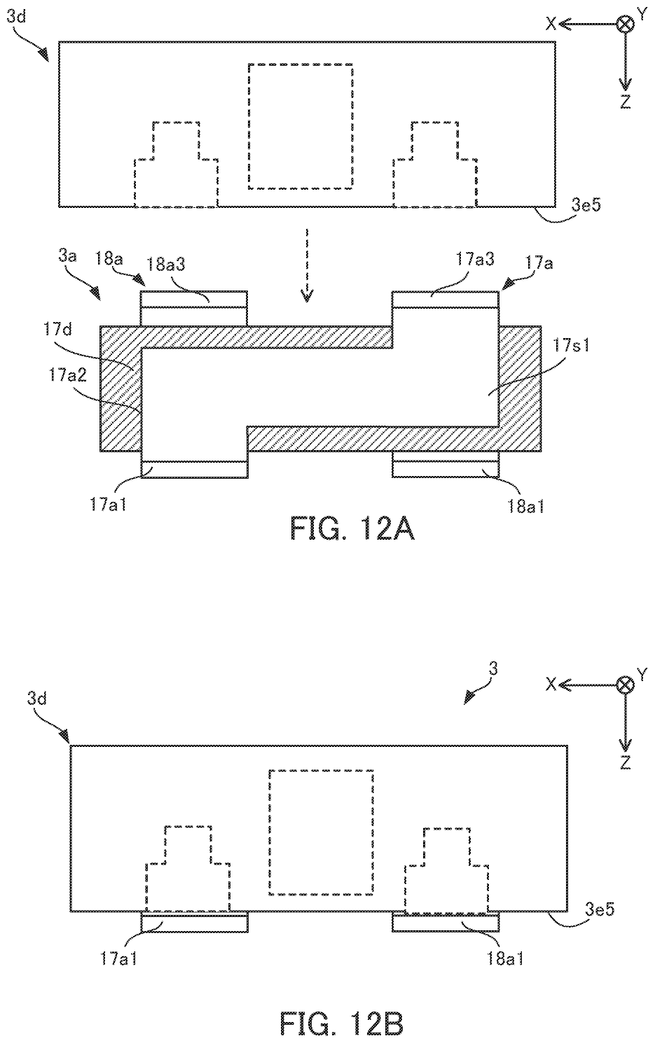

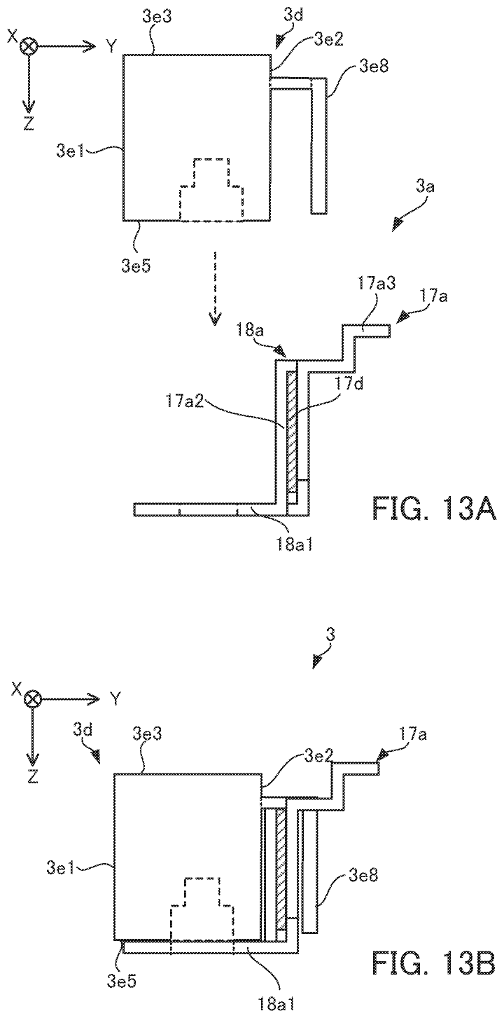

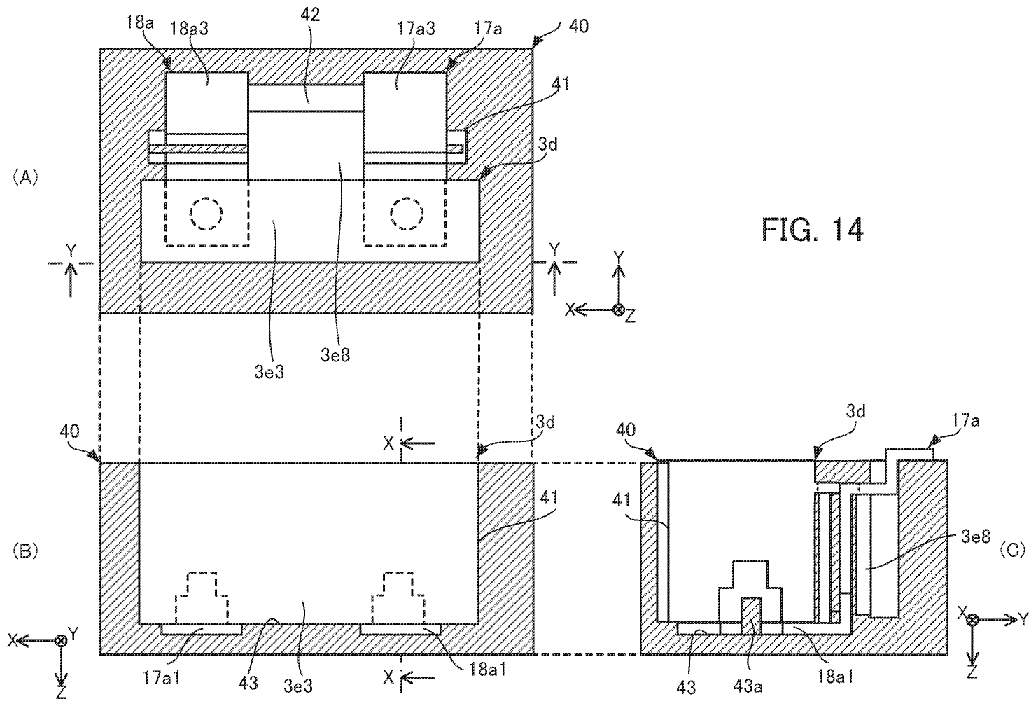

A second embodiment will be described with reference to FIGS. 11A to 14. Terminal units 3 according to the second embodiment differ from those according to the first embodiment. FIGS. 11A and 11B illustrate molding of a nut-embedded body with casing material, the molding being included in a preparation step for a casing according to the second embodiment. FIGS. 12A to FIG. 14 illustrate combining of molded bodies, the combining being included in the preparation step for the casing according to the second embodiment. FIG. 11B is a sectional view taken along a Y-Z plane in FIG. 11A and viewed in the X direction. FIG. 12A illustrates attachment of a nut-embedded body 3d to a terminal body 3a, and FIG. 12B is a side view of the attached nut-embedded body 3d viewed in +Y direction. FIG. 13A illustrates attachment of the nut-embedded body 3d to the terminal body 3a, and FIG. 13B is a side view of the attached nut-embedded body 3d viewed in the +X direction. (A) of FIG. 14 is a plan view of the terminal body 3a to which the nut-embedded body 3d has been attached and which has been stored in a molding fixture 40. (B) of FIG. 14 is a sectional view taken along a dashed-dotted line Y-Y in (A) of FIG. 14. (C) of FIG. 14 is a sectional view taken along a dashed-dotted line X-X in (B) of FIG. 14.

First, a nut-embedded body 3d according to the second embodiment will be described. As illustrated in FIGS. 11A and 11B, the individual nut-embedded body 3d includes nuts 30 and a nut main body 3e that seals the nuts 30. The nut-embedded body 3d illustrated in FIGS. 11A and 11B has a top surface 3e5, on which the nuts 30 are exposed to the outside and which faces downward. In addition, the nuts 30 and the casing material that constitutes the nut main body 3e are the same as those according to the first embodiment.

The nut main body 3e has the same structure as that of the nut main body 3e according to the first embodiment. That is, the nut main body 3e has the rectangular top surface 3e5 and a rectangular bottom surface 3e3 in plan view. The bottom surface 3e3 has the same shape and size as those of the top surface 3e5 and is located on the side opposite to the top surface 3e5. In addition, the nut main body 3e has a front surface 3e1, a side surface 3e4, a back surface 3e2, and a side surface 3e6, which sequentially surround the top surface 3e5 and the bottom surface 3e3 in plan view. The front surface 3e1 and the back surface 3e2 are located opposite each other and have the same size. The side surfaces 3e4 and 3e6 are located each other and have the same size. The nuts 30 are embedded in the top surface 3e5 of the nut main body 3e. The principal surface of each nut 30 and the top surface 3e5 are on the same plane. Alternatively, the principal surface of each nut 30 may be located lower than the top surface 3e5.

In addition, a sandwiching portion 3e8 is formed on the back surface 3e2 of the nut main body 3e. The sandwiching portion 3e8 is formed by two flat plates connected to each other at a right angle and has an L shape in side view. The ±X direction width of the sandwiching portion 3e8 may be less than the interval between the internal connection portions 17a3 and 18a3 of the terminal body 3a, as will be described below. In addition, a set of convex portions 3e9 are formed on the back surface 3e2, and another set of convex portions 3e9 are formed on the surface of the sandwiching portion 3e8, the surface facing the back surface 3e2. These sets of convex portions 3e9 face each other. This nut-embedded body 3d is molded by using a mold including an area corresponding to the sandwiching portion 3e8 in addition to the area corresponding to the nut-embedded body 3d according to the first embodiment.

Next, attachment of the nut-embedded body 3d to the terminal body 3a will be described. As illustrated in FIGS. 12A to 13B, the sandwiching portion 3e8 of the nut-embedded body 3d is moved in the direction from the internal connection portions 17a3 and 18a3 of the terminal body 3a toward the external connection portions 17a1 and 18a1 of the terminal body 3a between the internal connection portions 17a3 and 18a3, while sandwiching the wiring portions 17a2 and 18a2 and the insulating sheet 17d of the P and N terminals 17a and 18a.

In this way, the top surface 3e5 of the nut-embedded body 3d comes in contact with the external connection portions 17a1 and 18a1 of the P and N terminals 17a and 18a. As a result, the wiring portions 17a2 and 8a2 of the P and N terminals 17a and 18a and the insulating sheet 17d are sandwiched by the back surface 3e2 and the sandwiching portion 3e8 of the nut-embedded body 3d (a first resin portion). In this case, the nuts 30 in the nut-embedded body 3d respectively face the fastening holes 17h and 18h in the external connection portions 17a1 and 18a1 of the P and N terminals 17a and 18a. In this case, adhesive needs to be previously applied to at least one of the outer surface 17s1 of the wiring portion 17a2 of the P terminal 17a and the back surface 3e2 of the nut-embedded body 3d.

Next, assembling of the terminal body 3a to which the nut-embedded body 3d has been attached will be described. As illustrated in (A) and (B) of FIG. 14, the terminal body 3a to which the nut-embedded body 3d has been attached is set in the molding fixture 40.

The molding fixture 40 has a storage area 41 in which the terminal body 3a to which the nut-embedded body 3d has been attached is stored. Protruding portions 43a are formed on a bottom surface 43 of the storage area 41. The ±X-direction length of the storage area 41 matches the ±X-direction length of the terminal body 3a to which the nut-embedded body 3d has been attached. The ±Y-direction length of the storage area 41 matches the ±Y-direction length of the longest portion of the terminal body 3a to which the nut-embedded body 3d has been attached. The length of the longest portion is, for example, the distance between the front surface 3e1 of the nut-embedded body 3d and the internal connection portions 17a3 and 18a3 of the P and N terminals 17a and 18a in plan view. The depth of the storage area 41 matches the depth of the longest portion of the terminal body 3a to which the nut-embedded body 3d has been attached in the depth direction.

The terminal body 3a to which the nut-embedded body 3d has been attached is attached to the storage area 41 of the molding fixture 40. The top surface 3e5 of the terminal body 3a to which the nut-embedded body 3d has been attached and the external connection portions 17a1 and 18a1 come in contact with the bottom surface 43 of the molding fixture 40. In addition, the protruding portions 43a on the bottom surface 43 pass through the fastening holes 17h and 18h in the external connection portions 17a1 and 18a1 and are inserted into their respective nuts 30. These protruding portions 43a prevent the terminal body 3a to which the nut-embedded body 3d has been attached from being displaced in the storage area 41 of the molding fixture 40.

In addition, in plan view, a gap 42 is formed by the internal connection portions 17a3 and 18a3, the sandwiching portion 3e8, and the inner wall of the storage area 41. The gap 42 extends up to the bottom surface 43 of the storage area 41. This gap 42 functions as a back clearance that is useful when the sandwiching portion 3e8 of the nut-embedded body 3d is bent.

By attaching the terminal body 3a to which the nut-embedded body 3d has been attached to the above-described molding fixture 40, the terminal body 3a is sandwiched by the back surface 3e2 and the sandwiching portion 3e8 of the nut-embedded body 3d, and the nut-embedded body 3d is adhered to the terminal body 3a. The terminal unit 3 is obtained by removing the terminal body 3a to which the nut-embedded body 3d has been adhered from the molding fixture 40.

As in the first embodiment, the terminal units 3 formed as described above are set in a mold, and the casing material is injected into the mold. As a result, the casing 10 having the same advantageous effects as those according to the first embodiment is formed.

### Third Embodiment

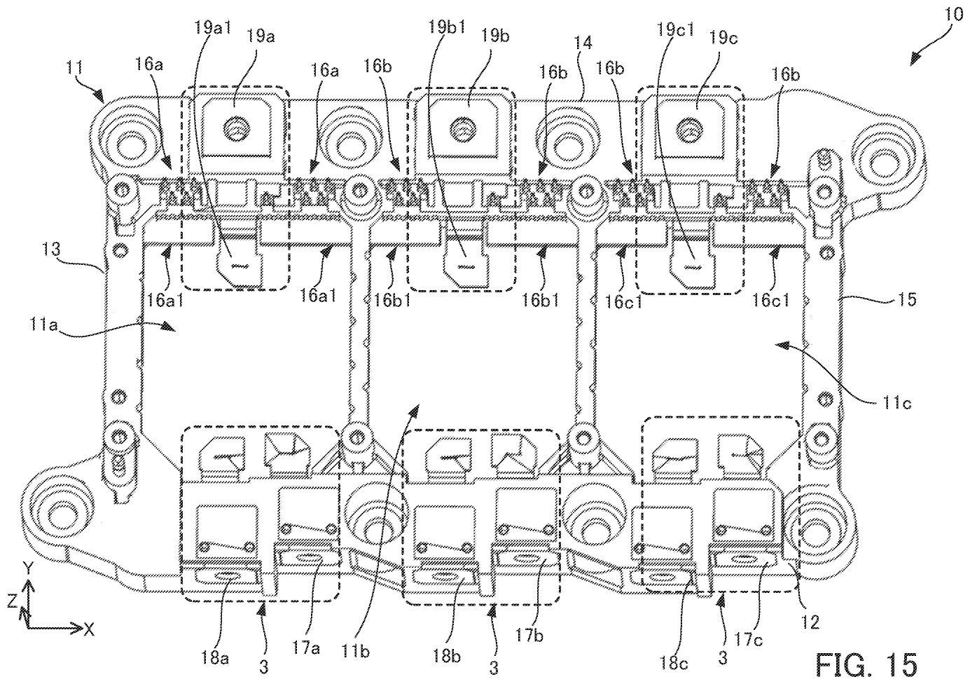

Next, a third embodiment will be described. For example, an individual terminal body according to the third embodiment differs from that according to the first embodiment. First, a casing 10 included in a semiconductor device according to the third embodiment will be described with reference to FIG. 15. FIG. 15 is a perspective view of a casing included in a semiconductor device according to the third embodiment.

This casing 10 according to the third embodiment also includes a frame portion 11, and P terminals 17a to 17c, N terminals 18a to 18c, and U, V, and W terminals 19a to 19c, all of which are molded integrally with the frame portion 11. These components are substantially the same as those according to the first embodiment. A long side portion 12 of the frame portion 11 integrally includes terminal units 3 including the P terminals 17a to 17c and the N terminals 18a to 18c. A long side portion 14 integrally includes terminal units (reference numerals are not illustrated) including the U, V, and W terminals 19a to 19c. However, external connection portions 17a1 and 18a1 of the P terminals 17a to 17c and the N terminals 18a to 18c are each exposed to the outside on a side portion (parallel to the X-Z plane) of the long side portion 12.

A semiconductor device 1 is obtained by disposing this casing 10 to a heatsink, to which the semiconductor units 2 according to the first embodiment have been bonded, such that the semiconductor units 2 are surrounded by their respective storage portions 11a to 11c.

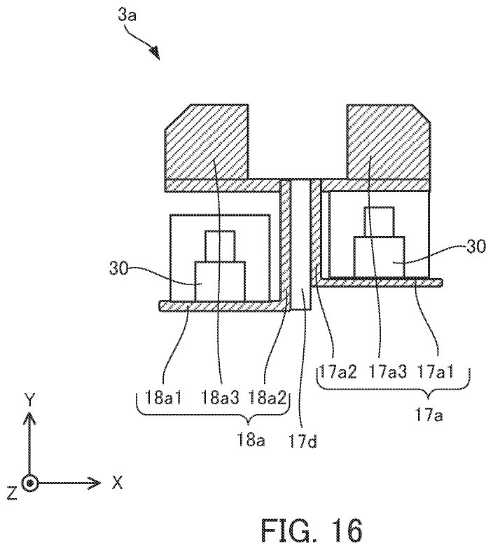

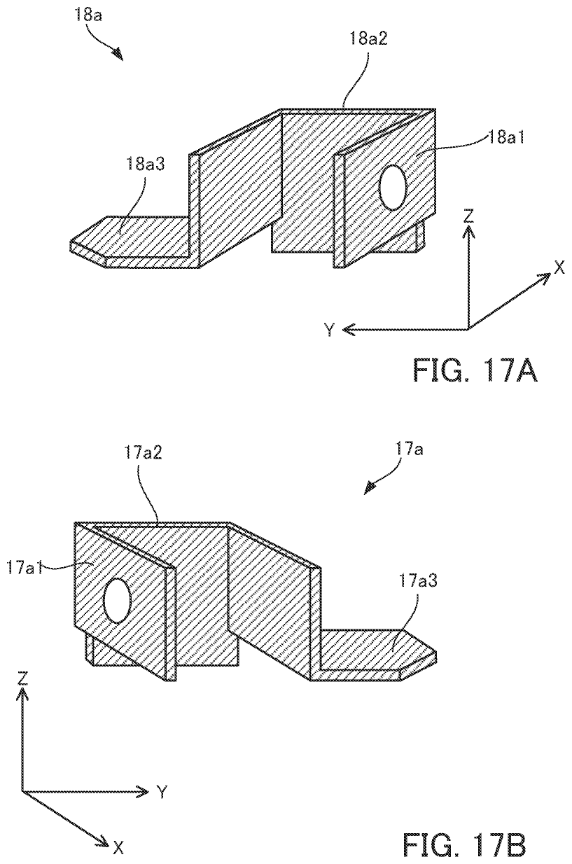

Next, a terminal unit 3 including a terminal body 3a and a terminal main body 3c that seals the terminal body 3a will be described. First, a terminal body 3a will be described with reference to FIG. 16 and FIGS. 17A and 17B. FIG. 16 illustrates assembling of a terminal body, the assembling being included in a preparation step for the casing according to the third embodiment. FIGS. 17A and 17B illustrate terminals included in the terminal body according to the third embodiment. FIG. 17A illustrates the N terminal 18a, and FIG. 17B illustrates the P terminal 17a.

The P terminal 17a includes an external connection portion 17a1, a wiring portion 17a2, and an internal connection portion 17a3. The external connection portion 17a1, the wiring portion 17a2, and the internal connection portion 17a3 each have a flat plate shape.

The external connection portion 17a1 has a fastening hole 17h, and faces in the −Y direction from the long side portion 12 of the frame portion 11, as will be described below. That is, the external connection portion 17a1 is parallel to the X-Z plane.

The wiring portion 17a2 is perpendicularly connected to the external connection portion 17a1. That is, the external connection portion is 17a1 formed to approximately perpendicularly extend from the wiring portion 17a2. The wiring portion 17a2 is connected integrally with the −X direction end portion of the external connection portion 17a1, and extends in the +Y direction perpendicularly from the external connection portion 17a1. That is, the wiring portion 17a2 is parallel to the Y-Z plane.

The internal connection portion 17a3 is connected to the +Y direction end portion of the wiring portion 17a2, and includes a flat plate portion perpendicular to the wiring portion 17a2 and a portion that is connected to the flat plate portion and that extends in the +Y direction perpendicularly from the flat plate portion. Thus, the external connection portion 17a1, the wiring portion 17a2, and the internal connection portion 17a3 constitute a U shape portion in plan view. A nut 30 is provided in this U shape portion. The fastening hole 17h in the external connection portion 17a1 matches the nut 30.

The N terminal 18a also includes an external connection portion 18a1, a wiring portion 18a2, and an internal connection portion 18a3. The external connection portion 18a1, the wiring portion 18a2, and the internal connection portion 18a3 each have a flat plate shape.

The external connection portion 18a1 has a fastening hole 18h, and faces in the −Y direction from the long side portion 12 of the frame portion 11, as will be described below. That is, the external connection portion 18a1 is parallel to the X-Z plane.

The wiring portion 18a2 is perpendicularly connected to the external connection portion 18a1. That is, the external connection portion 18a1 is formed to approximately perpendicularly extend from the wiring portion 18a2 in the opposite direction of the external connection portion 17a1. The wiring portion 18a2 is connected integrally with the +X direction end portion of the external connection portion 18a1, and extends in the +Y direction perpendicularly from the external connection portion 18a1. That is, the wiring portion 18a2 is parallel to the Y-Z plane. The wiring portion 18a2 faces the wiring portion 17a2.

The internal connection portion 18a3 is connected to the +Y direction end portion of the wiring portion 18a2, and includes a flat plate portion perpendicular to the wiring portion 18a2 and a portion that is connected to the flat plate portion and that extends in the +Y direction perpendicularly from the flat plate portion. Thus, the external connection portion 18a1, the wiring portion 18a2, and the internal connection portion 18a3 constitute a U shape portion in plan view. A nut 30 is provided in this U shape portion. The fastening hole 18h in the external connection portion 18a1 matches the nut 30.

An insulating sheet 17d has a rectangular shape in plan view and has an area that overlaps with the wiring portions 17a2 and 18a2. This insulating sheet 17d is sandwiched by the wiring portions 17a2 and 18a2 of the P and N terminals 17a and 18a. The insulating sheet 17d may have portions that extend more in the ±Y direction than the external connection portions 17a1 and 18a1.

FIG. 16 illustrates a case in which the external connection portion 18a1 of the N terminal 18a is located more in the −Y direction in plan view than the external connection portion 17a1 of the P terminal 17a. The external connection portion 18a1 of the N terminal 18a and the external connection portion 17a1 of the P terminal 17a may be on the same plane in plan view. Alternatively, the external connection portion 18a1 of the N terminal 18a may be located more in the +Y direction in plan view than the external connection portion 17a1 of the P terminal 17a.

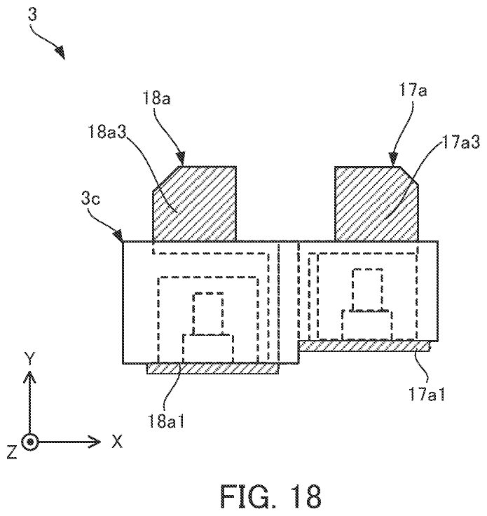

Next, a terminal unit 3 obtained by sealing the above-described terminal body 3a with a terminal main body 3c will be described with reference to FIG. 18. FIG. 18 illustrates molding of a terminal unit with casing material, the molding being included in a preparation step for the casing according to the third embodiment. FIG. 18 is a plan view of a terminal unit 3, and the portions covered by the terminal main body 3c are illustrated by dashed lines.

The terminal unit 3 illustrated in FIG. 18 is obtained by setting the terminal body 3a illustrated in FIG. 16 in a predetermined mold and injecting casing material into the mold. The terminal unit 3 includes the terminal body 3a and the terminal main body 3c that seals the terminal body 3a.

The terminal main body 3c has an approximately cuboid shape and seals the wiring portions 17a2 and 18a2, the insulating sheet 17d, and the nuts 30. In the case of the terminal main body 3c, the external connection portions 17a1 and 18a1 of the P and N terminals 17a and 18a are exposed to the outside in parallel to the X-Z plane. The internal connection portions 17a3 and 18a3 of the P and N terminals 17a and 18a extend in the +Y direction from the +Y direction surface of the terminal main body 3c. In addition, the −X direction side surface of the terminal main body 3c in plan view is located outside the external connection portion 18a1.

The +X direction side surface of the terminal main body 3c in plan view is located outside the external connection portion 17a1.

As in the first embodiment, the terminal unit 3 formed as described above is set in a mold, and casing material is injected into the mold. As a result, the casing 10 in FIG. 15 having the same advantageous effects as those according to the first embodiment is formed.

### Fourth Embodiment

Next, a casing 10 included in a semiconductor device

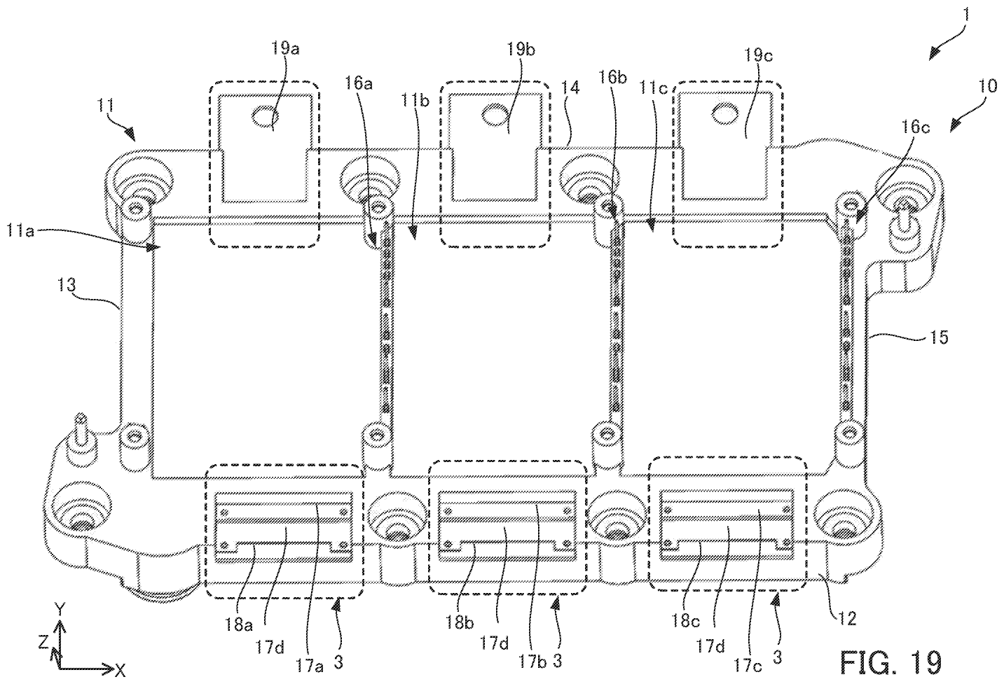

according to a fourth embodiment will be described with reference to FIG. 19. An individual terminal body according to the fourth embodiment differs from that according to the first embodiment. FIG. 19 is a perspective view of the casing included in the semiconductor device according to the fourth embodiment.

This casing 10 included in the semiconductor device 1 according to the fourth embodiment is also substantially the same as that according to the first embodiment, and includes a frame portion 11, and terminal units 3 and terminal units including U, V, and W terminals 19a to 19c, all of which are formed integrally with the frame portion 11. The semiconductor device 1 in FIG. 19 illustrates a case in which storage portions 11a to 11c are sealed with sealing material.

An N terminal 18a, an insulating sheet 17d, and a P terminal 17a included in a terminal unit 3 are sequentially stacked and are exposed to the outside on a side portion of a long side portion 12. The same applied to N terminals 18b and 18c, insulating sheets 17d, and P terminal 17b and 17c for the other terminal units 3. The terminal units 3 are formed in the ±X direction.

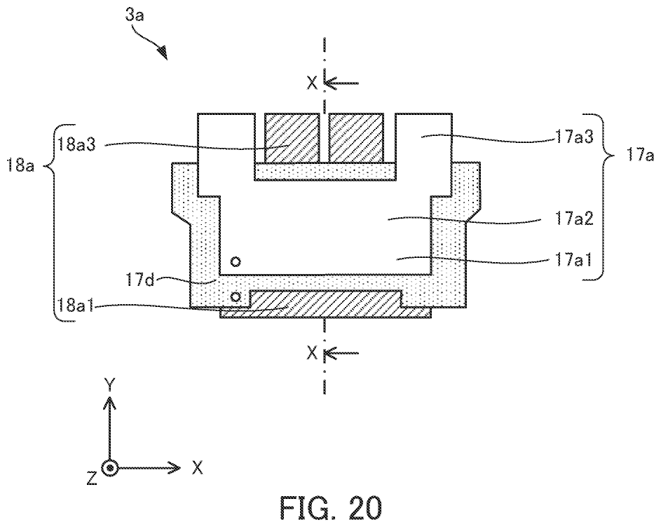

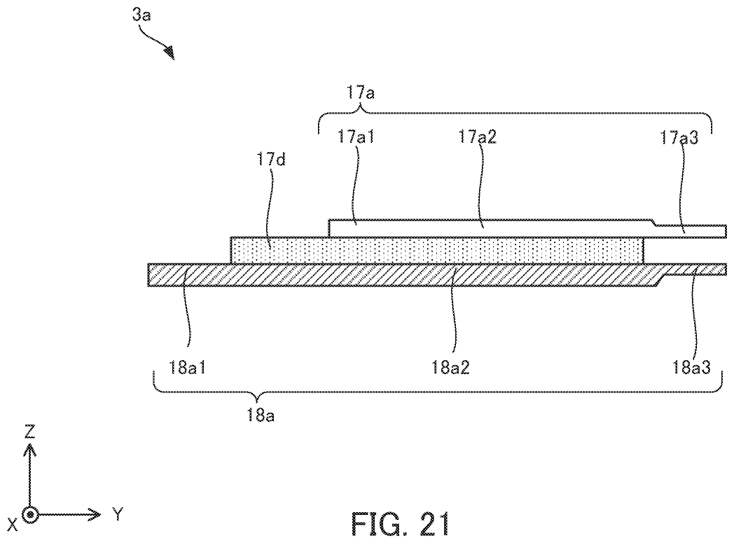

Next, a terminal body 3a included in the individual terminal unit 3 will be described with reference to FIGS. 20 and 21. FIGS. 20 and 21 illustrate assembling of a terminal body, the assembling being included in a preparation step for the casing according to the fourth embodiment. FIG. 21 is a sectional view taken along a dashed-dotted line X-X in FIG. 20.

As illustrated in FIGS. 20 and 21, the N terminal 18a, the insulating sheet 17d, and the P terminal 17a of the terminal body 3a are sequentially shifted in the +Y direction and stacked. The N terminal 18a has a flat plate shape and includes an external connection portion 18a1, a wiring portion 18a2, and an internal connection portion 18a3.

The external connection portion 18a1 is a portion that protrudes in the −Y direction more than the (−Y direction) end portion of the insulating sheet 17d. The wiring portion 18a2 is a portion that overlap with the insulating sheet 17d, and sandwiches the insulating sheet 17d with the P terminal 17a. The internal connection portion 18a3 is a portion that extends from the wiring portion 18a2 in the +Y direction.

The P terminal 17a has a flat plate shape and includes an external connection portion 17a1, a wiring portion 17a2, and an internal connection portion 17a3. The external connection portion 17a1 is a portion that is shifted more in the +Y direction from the (−Y direction) end portion of the insulating sheet 17d. The external connection portion 17a1 is also a portion that is exposed to the outside from the terminal main body 3c when the terminal body 3a is sealed with the terminal main body 3c, which will be described below. The wiring portion 17a2 is a portion that sandwiches the insulating sheet 17d with the N terminal 18a. The internal connection portion 17a3 is a portion that extends from the wiring portion 17a2 in the +Y direction.

The insulating sheet 17d is sandwiched by the N terminal 18a and the P terminal 17a. The insulating sheet 17d is not sandwiched by the internal connection portion 18a3 of the N terminal 18a and the internal connection portion 17a3 of the P terminal 17a. In plan view, the −Y direction end portion of the insulating sheet 17d is located between the external connection portion 18a1 of the N terminal 18a and the −Y direction end portion of the external connection portion 17a1 of the P terminal 17a. In addition, the ±X direction end portions of the insulating sheet 17d are located outside the ±X direction end portions of the N terminal 18a and the P terminal 17a.

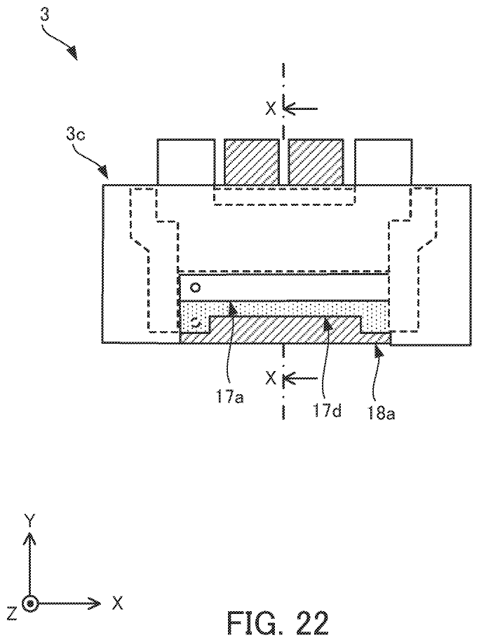

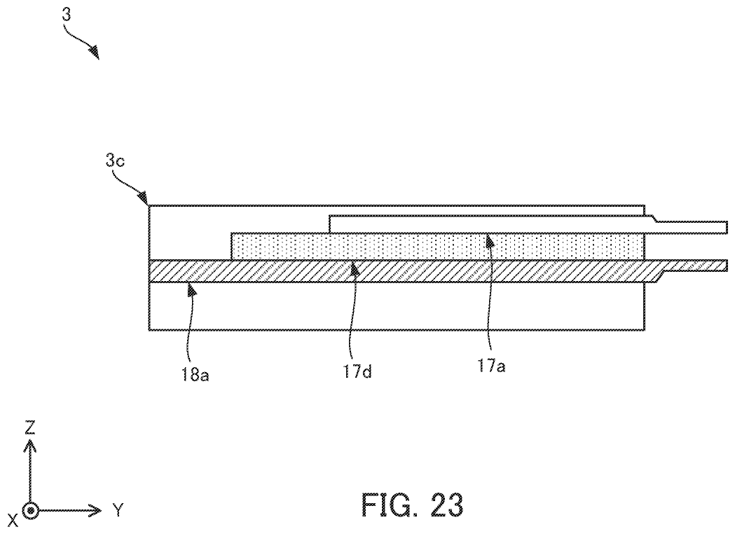

Next, a terminal unit 3 obtained by sealing the above-described terminal body 3a with a terminal main body 3c will be described with reference to FIGS. 22 and 23. FIGS. 22 and 23 illustrate molding of a terminal unit with casing material, the molding being include in the preparation step for the casing according to the fourth embodiment. FIG. 23 is a sectional view taken along a dashed-dotted line X-X inn FIG. 22. In addition, FIG. 22 is a plan view of a terminal unit 3, and the portions covered by the terminal main body 3c are illustrated by dashed lines.

The terminal unit 3 illustrated in FIGS. 22 and 23 is obtained by setting the individual terminal body 3a illustrated in FIGS. 20 and 21 in a predetermined mold and injecting casing material into the mold. Each terminal unit 3 includes the terminal body 3a and the terminal main body 3c that seals the terminal body 3a.

The terminal main body 3c has an approximately cuboid shape and seals the external connection portions 17a1 and 18a1, the wiring portions 17a2 and 18a2, and the insulating sheet 17d. The terminal main body 3c has an opening portion, which is rectangular in plan view, and this opening portion faces the X-Y plane and is located at the −Y direction side of the terminal main body 3c. Portions of the external connection portions 17a1 and 18a1 of the P and N terminals 17a and 18a and the insulating sheet 17d, which are stacked in a staircase pattern, are exposed to the outside in the opening portion of the terminal main body 3c. The internal connection portions 17a3 and 18a3 of the P and N terminals 17a and 18a extend from the +Y direction surface of the terminal main body 3c in the +Y direction. In addition, in plan view, the −X direction side surface of the terminal main body 3c is located outside the insulating sheet 17d. In plan view, the +X direction side surface of the terminal main body 3c is located outside the insulating sheet 17d.

As in the first embodiment, the individual terminal unit 3 formed as described above is set in a mold, and casing material is injected into the mold. As a result, the casing 10 in FIG. 19 having the same advantageous effects as those according to the first embodiment is formed.

An electronic device having the above-described construction and a manufacturing method of the electronic device achieve improvement in moldability of the casing and reduction in manufacturing cost of the casing.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An electronic device, comprising:
a first terminal having a first center portion, and a first external end portion and a first internal end portion that are respectively connected to opposing ends of the first center portion and respectively extend in a same direction or different directions that are opposite to each other;
a second terminal having a second center portion, and a second external end portion and a second internal end portion that are respectively connected to opposing ends of the second center portion and respectively extend in a same direction or different directions that are opposite to each other;
an insulating sheet sandwiched by the first and second center portions; and
a casing having a first resin portion in contact with the first and second center portions, and a second resin portion that holds the first resin portion, the first resin portion holding at least a part of the first and second terminals and the insulating sheet, with the first and second internal end portions and the first and second external end portions being exposed to an outside thereof.

2. An electronic device, comprising;
a first terminal having a first center portion, and a first external end portion and a first internal end portion that are respectively bent at opposing ends of the first center portion to extend in first and second directions that are opposite to each other;
a second terminal having a second center portion, and a second external end portion and a second internal end portion that are respectively bent at opposing ends of the second center portion to extend in the first and second directions;
an insulating sheet sandwiched by the first and second center portions; and
a casing having a first resin portion in contact with the first and second center portions, and a second resin portion that holds the first resin portion, the first resin portion holding at least a part of the first and second terminals and the insulating sheet with the first and second external end portions being exposed to an outside thereof.

3. The electronic device according to claim 2, wherein
the first center portion has a flat-plate rectangular shape with first and second long sides, and has a first opposing surface, which faces the second center portion and on which the insulating sheet is disposed,
the first external end portion is connected to one end portion of the first long side so as to be bent toward the first opposing surface, and
the first internal end portion is connected to one end portion of the second long side so as to be bent away from the first opposing surface, the one end portion of the first long side and the one end portion of the second long side being located diagonally opposite to each other with respect to the rectangular shape of the first center portion, and
the second center portion has a flat-plate rectangular shape with first and second long sides and has a second opposing surface, which faces the first center portion and which sandwiches the insulating sheet with the first opposing surface,
the second external end portion is connected to one end portion of the first long side so as to be bent toward the second opposing surface, and
the second internal end portion is connected to one end portion of the second long side so as to be bent away from the second opposing surface, the one end portion of the first long side and the one end portion of the second long side being located diagonally opposite to each other with respect to the rectangular shape of the second center portion.

4. The electronic device according to claim 3, wherein the first resin portion seals the first terminal, the insulating sheet and the second terminal, with the first and second external end portions and the first and second internal end portions being exposed to the outside thereof.

5. The electronic device according to claim 4, wherein
the first resin portion includes a nut-embedded body including first and second nuts and having first and second fastening holes for the first and second nuts, and a terminal-embedded body holding the nut-embedded body, the first terminal, the insulating sheet and the second terminal,
the nut-embedded body seals the first and second nuts, with the first and second fastening holes being exposed to the outside thereof, and is disposed on a first outer surface of the first center portion that is opposite to the first opposing surface, the first and second fastening holes respectively facing the first external end portion and the second external end portion, and
the terminal-embedded body stores the nut-embedded body and seals the first terminal, the insulating sheet and the second terminal, with the first and second external end portions and the first and second internal end portions being exposed to the outside thereof.

6. The electronic device according to claim 3, wherein the first resin portion includes a sandwiching portion that, along with the rest of the first resin portion, sandwiches a first outer surface of the first center portion that is opposite to the first opposing surface and a second outer surface of the second center portion that is opposite to the second opposing surface while pressing the first outer surface and the second outer surface against the insulating sheet.

7. The electronic device according to claim 6, wherein
the first resin portion further includes a nut-embedded body including first and second nuts and having first and second fastening holes for the first and second nuts,
the nut-embedded body is disposed on the first outer surface of the first center portion, the nut-embedded body sealing the first and second nuts, with the first and second fastening holes being exposed to the outside thereof, and
the sandwiching portion is provided on a back surface of the nut-embedded body that faces the first outer surface so that the first and second fastening holes respectively face the first external end portion and the second external end portion.

8. The electronic device according to claim 6, wherein the first internal end portion and the second internal end portion respectively extend to protrude from the sandwiching portion in the second direction.

9. The electronic device according to claim 2, wherein
the second resin portion has a frame shape that surrounds a rectangular storage area in a plan view of the electronic device, and
the first resin portion is included in a longitudinal side portion of the second resin portion, and the first internal end portion and the second internal end portion are exposed from the first resin portion to the storage area.

10. An electronic device manufacturing method, comprising:
preparing a case having a first resin portion and a second resin portion, and first and second terminals, and an insulating sheet, wherein
the first terminal has a first center portion, and a first external end portion and a first internal end portion that are respectively bent in directions that are opposite to each other, and
the second terminal has a second center portion, and a second external end portion and a second internal end portion that are respectively bent in directions that are opposite to each other;
disposing the first center portion of the first terminal, the insulating sheet and the second center portion of the second terminal to overlap one another;
bringing the first resin portion into contact with the first center portion and the second center portion, with at least a part of the first external end portion and at least a part of the second external end portion being exposed to an outside the first resin portion; and
molding the second resin portion to hold the first resin portion, thereby molding the case.
